(19) United States
(12) Patent Application Publication
(10) Pub. No.: US 2010/0264493 A1
(43) Pub. Date: Oct. 21, 2010

(54) SEMICONDUCTOR DEVICE AND MANUFACTURING METHOD THEREOF

(75) Inventors: Yasufumi IZUTSU, Toyama (JP); Kazuyuki SAWADA, Toyama (JP); Yuji HARADA, Toyama (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/731,267

(22) Filed: Mar. 25, 2010

(30) Foreign Application Priority Data
Apr. 15, 2009 (JP) 2009-099378

(51) Int. Cl. H01L 29/06; H01L 21/336; H01L 29/78

(52) U.S. Cl. 257/355; 438/197; 257/E21.409; 257/E29.255; 257/E29.024

(57) ABSTRACT

To provide a semiconductor device which includes a P-type Si substrate, an ESD protection element, and a protected element. The ESD protection element includes a source N-type diffusion region, and a high-concentration P-type diffusion region formed from under the source N-type diffusion region to at least under part of a gate electrode, covering the source N-type diffusion region within the P-type Si substrate, and having a higher P-type impurity concentration than the P-type Si substrate. The protected element includes a drain N-type diffusion region, and a low-concentration P-type diffusion region that is in contact with the drain N-type diffusion region within the P-type Si substrate. The drain electrode of the ESD protection element and the drain electrode of the protected element are connected, and the high-concentration P-type diffusion region 103 has a higher P-type impurity concentration than the low-concentration P-type diffusion region.

### BACKGROUND OF THE INVENTION

(1) Field of the Invention

The present invention relates to semiconductor devices, and particularly to a semiconductor device equipped with a protection circuit against electrostatic discharge (ESD) and to a manufacturing method thereof.

(2) Description of the Related Art

In general, with semiconductor devices, semiconductor elements of internal circuits are prone to damage due to surges caused by electrostatic discharge (ESD) from the outside of the device, and thus many semiconductor devices have a built-in protection circuit.

The diode-type, transistor-type, and thyristor-type can be given as representative types of ESD protection circuits. Their uses are varied depending on their response speed or discharge capacity as a protective circuit, and the constraints from the surface area required on a semiconductor chip, and so on. Among the aforementioned types, MOS transistor-type ESD protection circuits, which can be formed in the same process flow and is advantageous in terms of required surface area and discharge capacity, are generally used in the MOS transistor manufacturing process.

The configuration and operation of an ESD protection circuit shown in Japanese Unexamined Patent Application Publication No. 2007-5825 (Patent Reference 1) shall be described hereafter as a conventional example.

FIG. 12 is a cross-section schematic diagram of a MOS transistor-type protection element making up an ESD protection circuit. In the MOS transistor-type protection element illustrated in the figure, a gate electrode 903 is formed above a P-type semiconductor substrate 901 via a gate insulating film 902. Furthermore, a source N-type diffusion region 904A and a drain N-type diffusion region 904B are formed on both sides of the gate electrode 903, within the semiconductor substrate 901. In addition, under the drain N-type diffusion region 904B, a high-concentration P-type diffusion region 905 is formed in contact with the drain N-type diffusion region 904B. Furthermore, a silicide layer 906A and a silicide layer 906B are formed on the upper surface of the source N-type diffusion region 904A and the drain N-type diffusion region 904B, respectively. Furthermore, a source contact wire 908A and a drain contact wire 908B are formed above the semiconductor substrate 901 through contact holes provided in an inter-layer insulating film 907 formed on the semiconductor substrate 901.

In a MOS transistor-type protection element configured in such a manner, when a surge voltage is applied to an external connection pad connected to the drain contact wire 908B, there is an abrupt increase in the potential of the drain N-type diffusion region 904B whose surface has a resistance that has been lowered by the silicide layer 906B. With this, electron-hole pairs are generated by the impact ionization phenomenon in the P-N junction between the drain N-type diffusion region 904B and the P-type diffusion region 905. The holes generated here flow into the P-type semiconductor substrate 901 and become a discharge current. The discharge current brings about an increase in the potential inside the semiconductor substrate 901, due to the unique and limited resistance of the semiconductor substrate 901. As a result, the lateral parasitic bipolar transistor made up of the drain N-type diffusion region 904B, the semiconductor substrate 901, and the source N-type diffusion region 904A becomes conductive. With this, a large current flows from the drain contact wire 908B to the source contact wire 908A, and the surge voltage can be allowed to escape to a ground line as current.

FIG. 13 is a graph showing the discharging characteristics of the ESD protection circuit. In the graph shown in the figure, the horizontal axis denotes the drain terminal voltage of the ESD protection circuit, and the vertical axis denotes the drain current flowing from the drain to the source of the ESD protection circuit. Furthermore, in the circuit configuration in this case, the drain terminal is connected to the external input-output terminals of the protected element (component of an internal circuit), and thus the aforementioned drain terminal voltage is also equivalent to the voltage applied to the terminal of the protected element. The relationship between the operation of the ESD protection circuit and the graph shown in FIG. 13 shall be described hereafter.

When a surge voltage is applied to the drain terminal of the ESD protection circuit from the outside, the drain terminal voltage increases abruptly, and the lateral parasitic bipolar transistor shown in FIG. 12 becomes conductive when the drain terminal voltage reaches the protection-operation starting voltage (hereafter called Vt1). At this time, current flows from the drain terminal towards the source terminal and, due to the snapback phenomenon, the drain terminal voltage deteriorates up to a holding voltage (hereafter called Vh) which is the minimum value of voltage generated between the drain and the source. Subsequently, the protected element of the internal circuit, connected to the drain terminal can be protected by transition to the main discharging operation. Characteristic R1 (broken line) shown in FIG. 13 denotes the aforementioned operation.

With the conventional ESD protection circuit described in Patent Reference 1, a high-concentration P-type diffusion region 905 is formed directly below the drain terminal through which the surge voltage comes in and the drain N-type diffusion region 904B. Therefore, a steep P-N junction having a wide surface area is formed in the interface between the drain N-type diffusion region 904B and the P-type diffusion region 905. Accordingly, with the incoming of the surge voltage, avalanche breakdown occurs easily and thus the parasitic bipolar transistor becomes conductive efficiently, with a lower drain voltage. Specifically, the above-described ESD protection circuit is designed to be able to complete the protection of the internal circuit against surge application from outside, with the lowest possible voltage and in a short time, by reducing Vt1 in the direction of arrow S shown in FIG. 13. Characteristic R2 (solid line) shown in FIG. 13 denotes the above-described operation.

However, the conventional ESD protection circuit described in Patent Reference 1 has, as a basic structure, a MOS transistor having a drain withstand voltage equal to that of the internal circuit, and is merely a configuration which is able to reduce the protection-operation starting voltage (Vt1).

In contrast, in an actual circuit configuration, even when surge voltage is not applied from the outside, there are instances where the substrate potential increases in the vicinity of the protection element due to the incidental combination of substrate current and power source noise during the normal operation of the internal circuits (the protected element and the other circuits). When such situation arises, the lateral parasitic bipolar transistor included in the protection element becomes conductive even when the drain terminal voltage of the protection element does not reach Vt1. With this, aside from when surge voltage is applied, there are instances where, even during normal operation, the power source voltage of the internal circuit significantly deteriorates, and so on, by following a path such as that of characteristic R3 shown in FIG. 13, and such power source voltage deterioration becomes a cause of circuit malfunction.

### SUMMARY OF THE INVENTION

The present invention is conceived in view of the aforementioned problem and has as a first object to provide a semiconductor device including a protection circuit that prevents the triggering of internal circuit malfunctioning. In addition, a second object is to provide a configuration, and a manufacturing method thereof, for appropriately protecting the inner circuits against surges from the outside, and implementing the semiconductor device efficiently and at a lower cost.

In order to solve the aforementioned problem, the semiconductor device in an aspect of the present invention is a semiconductor device including: a semiconductor substrate of a second conductivity type; an internal circuit composed of a transistor element using the semiconductor substrate; and a protection circuit which protects the internal circuit against electrostatic discharge and is a transistor element using the semiconductor substrate, wherein the protection circuit includes: a first gate electrode which is formed above the semiconductor substrate and is grounded; and a first electrode and a second electrode which are formed on the semiconductor substrate, each at an opposite side with respect to the first gate electrode, the first electrode and the second electrode being formed apart from the first gate electrode, and the second electrode being grounded; a first diffusion region which is formed within the semiconductor substrate and is in contact with the second electrode, the first diffusion region being of a first conductivity type that is opposite in conductivity to the second conductivity type; and a second diffusion region which is formed from under the first diffusion region to at least under part of the first gate electrode and covers the first diffusion region within the semiconductor substrate, the second diffusion region having a higher impurity concentration than an original region of the semiconductor substrate and being grounded at a same level as the first diffusion region, the internal circuit includes: a second gate electrode formed above the semiconductor substrate; a third electrode and a fourth electrode which are formed on the semiconductor substrate, each at an opposite side with respect to the second gate electrode, the third electrode and the fourth electrode being formed apart from the second gate electrode, and a third diffusion region which is formed under the third electrode and within the semiconductor substrate, and which is of the first conductivity type; and a fourth diffusion region which is formed within the semiconductor substrate and has a highest second conductivity-type impurity concentration among regions in contact with the third diffusion region, the third electrode is connected to the first electrode, and the second diffusion region has a higher second conductivity-type impurity concentration than the fourth diffusion region.

By adopting the above-described configuration, the impurity elemental concentration of the second diffusion region, which is the region corresponding to the base of the parasitic bipolar transistor formed between the drain and the source of the protection circuit, becomes higher than the impurity elemental concentration of the fourth diffusion region of the internal circuit. Specifically, the base resistance of the parasitic bipolar transistor decreases relatively, and the increase of the base potential with respect to drain voltage, substrate current, and power source noise can be suppressed. Accordingly, in the case of forming an internal circuit and a protection circuit having a MOS-type FET structure on the same substrate, it becomes possible to improve the holding voltage (Vh) which is the minimum value of the drain voltage when the parasitic bipolar transistor is ON, compared to the conventional protected circuit in which the protection-operation starting voltage (Vt1) is merely set lower than the withstand voltage of the internal circuit.

Therefore, it becomes possible to prevent the power source voltage of the internal circuit from deteriorating significantly and triggering circuit malfunction.

Furthermore, it is preferable that a holding voltage, which is a characteristic value of the protection circuit, is higher than a maximum operating power source voltage at which normal operation of the internal circuit is guaranteed, the holding voltage being a minimum value of voltage generated between the first electrode and the second electrode immediately after conduction is created between the first electrode and the second electrode.

Accordingly, even when the parasitic bipolar transistor is ON, the drain voltage of the protection circuit can be maintained at a higher voltage than the maximum operating power source voltage of the internal circuit. Therefore, power source voltage deterioration and circuit malfunctioning of the internal circuit can be prevented.

Furthermore, it is preferable that the protection circuit further includes: a fifth diffusion region which is formed within the semiconductor substrate and is near or in contact with the first diffusion region and is in contact with the second diffusion region, the fifth diffusion region having a higher second conductivity-type impurity concentration than the second diffusion region, and a fifth electrode which is formed on the semiconductor substrate, in contact with the fifth diffusion region, and which is grounded.

Since the fifth diffusion region is of the second conductivity type like the second diffusion region, in terms of being a substrate current path, the path to the fifth diffusion region has a lower resistance than the path to the first diffusion region. Furthermore, since the first diffusion region of the first conductivity type and the fifth diffusion region of the second conductivity type are disposed near or in contact with each other, most of the substrate current passes the second diffusion region and passes through the current path of the fifth diffusion region which has a lower resistance than the current path to the first diffusion region. At least, at a P-N junction forward direction ON voltage of 0.7V or lower, almost all the substrate current that flows to the second diffusion region flows to the fifth diffusion region. In the present configuration, the resistance of a second conductivity-type region is reduced at the emitter-side, that is, the source-side, of the parasitic bipolar transistor, and the fifth region connected to the second conductivity-type region is grounded.

Accordingly, by suppressing the potential at the source-side, the potential difference between the base and the emitter of the parasitic bipolar transistor can be reduced. Therefore, an increase in the base potential of the parasitic bipolar transistor can be suppressed. This means that the conductive state is not realized unless the drain voltage becomes a higher potential, and this means increasing Vh. Therefore, power source voltage deterioration and circuit malfunctioning of the internal circuit can be prevented.

Furthermore, the semiconductor device may include plural protection circuits including the protection circuit each of which is disposed corresponding to one of plural internal circuits including the internal circuit, wherein the second conductivity-type impurity concentration of the second diffusion region may be set separately for each of the protection circuits.

Accordingly, even when internal circuits of different withstand voltage or operating power source voltage are formed on the same substrate, Vh can be set independently for the protection circuits for protecting the respective internal circuits. Therefore, the triggering of malfunctioning of internal circuits located in the periphery of a protection circuit by the protection-operation of such protection circuit can be prevented.

Furthermore, it is preferable that the protection circuit further includes: a sixth diffusion region which is formed within the semiconductor substrate and is in contact with the first electrode, the sixth diffusion region being of the first conductivity type; and a seventh diffusion region which is formed within the semiconductor substrate and is in contact with the sixth diffusion region, the seventh diffusion region being of the second conductivity type, and the seventh diffusion region has a higher second conductivity-type impurity concentration than the fourth diffusion region when the third diffusion region is in contact with the third electrode.

The withstand voltage of the internal circuit is dependent on the reverse withstand voltage of the P-N junction formed in the diffusion regions below the third electrode (for example, a drain). On the other hand, Vt1 of the protection circuit is dependent on the reverse withstand voltage of the P-N junction formed between the sixth (for example, N-type) diffusion region and the seventh (for example, P-type) diffusion region below the first region (for example, a drain). The reverse withstand voltage increases as the P-type concentration and the N-type concentration in the respective P-type region and N-type region making up the P-N junction decrease. In the case of structure of an internal circuit having a normal withstand voltage in which the third (for example N-type) diffusion region is formed directly under the third electrode (for example, a drain) and such region and the fourth (for example, p-type) diffusion region are in contact, and the typical third (for example, N-type) diffusion region and the sixth (for example, N-type) diffusion region have the same concentration, Vt1 can be set lower than the withstand voltage of the internal circuit by setting the second conductivity-type (for example, P-type) concentration of the seventh (for example, P-type) diffusion region higher than that of the fourth (for example P-type) diffusion region. Therefore, in the case of an output transistor having a drain-side with the same structure, the protection circuit can be made to operate before the internal circuit becomes conductive, and thus the internal circuit can be appropriately protected against surge voltage from the outside.

Furthermore, the seventh diffusion region may be formed from under the sixth diffusion region to under the first gate electrode and may cover the sixth diffusion region within the semiconductor substrate.

Since the seventh (for example, P-type) diffusion region covers the sixth (for example, N-type) diffusion region, Vt1 of the protection circuit is determined according to the P-N junction formed by these two regions. Therefore, even when the seventh (for example, P-type) diffusion region is in contact with the high-concentration second (for example, P-type) diffusion region below the gate electrode, Vt1 does not deteriorate excessively. Thus, high-precision injection and diffusion processes in which the seventh (for example, P-type) diffusion region and the second (for example, P-type) diffusion region are not in contact are not required, and the manufacturing process can be simplified. Furthermore, the second (for example, P-type) diffusion region which affects Vh and the seventh (for example, P-type) diffusion region which affects Vt1 can be controlled independently, and thus Vt1 and Vh can be set separately.

Furthermore, the seventh diffusion region may be not formed under the first gate electrode and may be formed apart from the second diffusion region, the seventh diffusion region having a lower second conductivity-type impurity concentration than the second diffusion region.

The Vt1 of the protection circuit is dependent on the reverse withstand voltage of the P-N junction formed below the first electrode (for example, a drain), and such reverse withstand voltage increases as the P-type concentration and the N-type concentration in the respective P-type region and the N-type region making up such P-N junction decrease. However, since the seventh (for example, P-type) diffusion region is formed apart from the second (for example, P-type) diffusion region, Vt1 is not affected by the second (for example, P-type) diffusion region. Therefore, the second (for example, P-type) diffusion region which influences Vh and the seventh (for example, P-type) diffusion region which influences Vt1 can be controlled independently, and thus Vt1 and Vh can be set separately.

Furthermore, the protection circuit further may include: a sixth diffusion region which is formed within the semiconductor substrate and is in contact with the first electrode, the sixth diffusion region being of the first conductivity type; and a seventh diffusion region which is formed within the semiconductor substrate and is in contact with the sixth diffusion region, the seventh diffusion region being of the second conductivity type, the third diffusion region may have a lower first conductivity-type impurity concentration than the sixth diffusion region, and the seventh diffusion region may have a second conductivity-type impurity concentration equal to or higher than the second conductivity-type impurity concentration of the original region of the semiconductor substrate.

In the case of a structure in which the third diffusion region having a lower N-type concentration than the sixth diffusion region is present under the third electrode (for example, a drain), and the third diffusion region is in contact with the fourth diffusion region, Vt1 can be set lower than the withstand voltage of the internal circuit by setting the second conductivity-type (for example, P-type) concentration of the seventh (for example, P-type) diffusion region to be equal to or higher than that of the original region of the semiconductor substrate. Therefore, the internal circuit can be appropriately protected against surge voltage from the outside.

Furthermore, the semiconductor device may include plural protection circuits including the protection circuit each of which is disposed corresponding to one of plural internal circuits including the internal circuit, wherein the second conductivity-type impurity concentration of the seventh diffusion region may be set separately for each of the protection circuits.

Accordingly, even when internal circuits of different withstand voltage are formed on the same substrate, Vt1 can be set independently for the protection circuits for protecting the respective internal circuits. Therefore, the triggering of malfunctioning of internal circuits located in the periphery of a protection circuit by the protection-operation of such protection circuit can be prevented.

It should be noted that the present invention can be implemented, not only as a semiconductor device including such characteristic units, but also as a semiconductor device manufacturing method having the characteristic units included in the semiconductor device as steps.

In order to solve the aforementioned problem, the method for manufacturing a semiconductor device in an aspect of the present invention is a method for manufacturing a semiconductor device, the semiconductor device including: a semiconductor substrate of a second conductivity type; an internal circuit composed of a transistor element using a first region of the semiconductor substrate; a protection circuit which protects the internal circuit against electrostatic discharge and is a transistor element using a second region of the semiconductor substrate, the second region being different from the first region, and the method including: forming the internal circuit; and forming the protection circuit, wherein the forming of a protection circuit includes: forming a first injection region on a surface of the semiconductor substrate of the second conductivity type by blanket irradiating an ion species of the second conductivity type, the first injection region having a higher second conductivity-type impurity concentration than an original region of the semiconductor substrate that is not injected with the ion species; forming a second injection region and a third injection region on the surface of the semiconductor substrate by opening at least parts of the first injection region and blanket irradiating an ion species of the second conductivity type after the forming of a first injection region, the second injection region having a second conductivity-type impurity concentration equal to or higher than a second conductivity-type impurity concentration of the original region, and the third injection region having a higher second conductivity-type impurity concentration than the second injection region; heat-diffusing the second injection region and the third injection region to create a medium-concentration diffusion region and a high-concentration diffusion region, respectively, by heat-treating the semiconductor substrate after the forming of a second injection region and a third injection region; forming a first gate electrode on the surface of the semiconductor substrate after the heat-diffusing so that the first gate electrode is in contact with the high-concentration diffusion region and is near or is in contact with the medium-concentration diffusion region; forming a first surface diffusion region and a second surface diffusion region, which are of the first conductivity type, in part of the medium-concentration diffusion region and part of the high-concentration diffusion region, respectively, within the semiconductor substrate and near the surface of the semiconductor substrate, after the forming of a first gate electrode; and forming a first electrode and a second electrode on the surface of the semiconductor substrate after the forming of a first surface diffusion region and a second surface diffusion region, the first electrode being connected to the internal circuit and in contact with only the first surface diffusion region, and the second electrode being in contact with only the second surface diffusion region.

Accordingly, the amount of impurity introduced to the medium-concentration diffusion region and the high-concentration diffusion region can be controlled independently, and thus Vt1 and Vh can be set separately. Furthermore, since the forming process for the high-concentration diffusion region shares the forming process of the medium-concentration diffusion region, there is the advantage of being able to suppress an increase in the number of processes.

Furthermore, the forming of an internal circuit may include: forming an internal circuit diffusion region on the surface of the semiconductor substrate by injecting an ion species of the second conductivity type into the surface of the semiconductor substrate, the internal circuit diffusion region having a higher second conductivity-type impurity concentration than the original region; forming a second gate electrode on the surface of the semiconductor substrate after the forming of an internal circuit diffusion region; forming a third surface diffusion region and a fourth surface diffusion region within the semiconductor substrate, each at an opposite side with respect to the second gate electrode, after the forming of a second gate electrode; and forming a third electrode and a fourth electrode on the surface of the semiconductor substrate after the forming of a third surface diffusion region and a fourth surface diffusion region, the third electrode being connected to the first electrode of the protection circuit and in contact with only the third surface diffusion region, and the fourth electrode being in contact with only the fourth surface diffusion region, in the forming of an internal circuit diffusion region, the internal circuit diffusion region may be formed by blanket irradiating the ion species of the second conductivity type simultaneously with the forming of a first injection region or the forming of a second injection region and a third injection region, in the forming of a third surface diffusion region and a fourth surface diffusion region, the third surface diffusion region and the fourth surface diffusion region may be formed by blanket irradiating an ion species of the first conductivity type simultaneously with the forming of a first surface diffusion region and a second surface diffusion region, in the forming of a third electrode and a fourth electrode, the third electrode and the fourth electrode may be formed simultaneously with and in a same process as the forming of a first electrode and a second electrode, and in the forming of a first injection region, the forming of a second injection region and a third injection region, and the heat-diffusing, the high-concentration diffusion region may be formed so as to have a higher second conductivity-type impurity concentration than a region of the second conductivity type which is formed within the semiconductor substrate and is in contact with or is near the third surface diffusion region.

Accordingly, since all the manufacturing processes required in the forming of the protection circuit can be included in the manufacturing processes for the internal circuit, the desired protection circuit can be built into the semiconductor device without adding new processes. Therefore, there is an advantage of being able to suppress an increase in the number of processes.

Furthermore, the method for manufacturing a semiconductor device may further include: forming a power transistor included in the semiconductor device, wherein the forming of a power transistor may include: forming a low-concentration diffusion region which serves as an extension drain of the first conductivity type, by injecting an ion species of the first conductivity type into a surface of a third region of the semiconductor substrate that is different from the first region; forming a first power transistor diffusion region in part of the low-concentration diffusion region after the forming of a low-concentration diffusion region, the first power transistor diffusion region having a higher second conductivity-type impurity concentration than the original region of the semiconductor substrate; and forming a second power transistor diffusion region within the semiconductor substrate, in a region other than the low-concentration diffusion region, after the forming of a low-concentration diffusion region, the second power transistor diffusion region having a higher second conductivity-type impurity concentration than the original region, and in the forming of a first power transistor diffusion region and the forming of a second power transistor diffusion region, the first power transistor diffusion region and the second power transistor diffusion region may be respectively formed by blanket irradiating an ion species of the second conductivity type simultaneously with the forming of a first injection region and the forming of a second injection region and a third injection region.

Although the method for manufacturing a semiconductor device according to the present invention is executed by being built into the manufacturing process of a typical MOS transistor, by sharing processes with a manufacturing process including processes suited to second conductivity- (for example, P-) type ion injection, for example, a power transistor manufacturing process, there is an advantage of being able to suppress an increase in the number of processes. For example, the manufacturing process for an extension drain-structure NMOS power transistor includes, prior to the process of forming a gate electrode, processes of forming an N-type diffusion region for extending the drain portion and forming a P-type diffusion region for controlling the depletion layer of the extension drain, in order to increase the drain withstand voltage. The above-described process of forming the P-type diffusion region is suitable for the P-type region concentration control performed in the present invention.

According to the semiconductor device in the present invention, since it is possible to improve the holding voltage when the parasitic bipolar transistor of the protection circuit is ON and, in addition, it is possible to set the protection-operation starting voltage lower than the withstand voltage of the internal circuit, malfunctioning of the internal circuit can be prevented and, in addition, the internal circuit can be appropriately protected against surges from the outside. Furthermore, according to the method for manufacturing a semiconductor device in the present invention, since the diffusion region forming processes for the protection circuit and the internal circuit can be shared, the semiconductor device can be implemented efficiently and with lower cost.

### FURTHER INFORMATION ABOUT TECHNICAL BACKGROUND TO THIS APPLICATION

The disclosure of Japanese Patent Application No. 2009-099378 filed on Apr. 15, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a structural cross-sectional view showing the main section of an ESD protection element and a protected element included in a semiconductor device in a first embodiment of the present invention;

FIG. 2 is a graph showing a comparison of the discharging characteristics of the present invention and a conventional ESD protection circuit;

FIG. 3 is a typical circuit configuration diagram showing the connection relationship between the protection circuit and the internal circuits;

FIG. 4A is a structural cross-sectional view of an ESD protection element representing a first modification of the semiconductor device in the first embodiment of the present invention;

FIG. 4B is a structural cross-sectional view of an ESD protection element representing a second modification of the semiconductor device in the first embodiment of the present invention;

FIG. 5 is a structural cross-sectional view showing the main section of an ESD protection element and a protected element included in a semiconductor device in a second embodiment of the present invention;

FIG. 6 is a structural cross-sectional view of an ESD protection element representing a modification of the semiconductor device in the second embodiment of the present invention:

FIG. 7 is a structural cross-sectional view showing the main parts of an ESD protection element and a protected element included in a semiconductor device in a third embodiment of the present invention;

FIG. 8 is a structural cross-sectional view showing the main parts of an ESD protection element and a protected element included in a semiconductor device in a fourth embodiment of the present invention;

FIG. 9 is process cross-sectional view showing a method for manufacturing a semiconductor device in a fifth embodiment of the present invention;

FIG. 10 is process cross-sectional view showing a method for manufacturing the semiconductor device in the fifth embodiment of the present invention;

FIG. 11 is process cross-sectional view showing a method for manufacturing a semiconductor device in a sixth embodiment of the present invention;

FIG. 12 is a cross-sectional schematic diagram of a MOS transistor-type protection element making up an ESD protection circuit; and

FIG. 13 is a graph showing the discharging characteristics of the ESD protection circuit.

### DESCRIPTION OF THE PREFERRED EMBODIMENT(S)

### First Embodiment

A semiconductor device in the present embodiment includes an internal circuit and a protection circuit using the same P-type semiconductor substrate. The aforementioned protection circuit includes: a grounded first gate electrode, a grounded first source electrode, and a first drain electrode which are formed above the P-type semiconductor substrate; a first diffusion region of N-type which is in contact with the first source electrode, within the P-type semiconductor substrate; and a second diffusion region which is formed from under the first diffusion region to at least under part of the first gate electrode and covers the first diffusion region within the P-type semiconductor substrate, and which has a higher P-type concentration than an original region of the P-type semiconductor substrate, and is grounded at the same level as the first diffusion region. Furthermore, the aforementioned internal circuit includes: a second gate electrode, a second source electrode, and a second drain electrode which are formed above the P-type semiconductor substrate; a third diffusion region of N-type formed under the second drain electrode, within the P-type semiconductor substrate; and a fourth region of P-type which is in contact with the third diffusion region, within the P-type semiconductor substrate. In the above-described configuration, the second drain electrode and the first drain electrode are connected, and the second diffusion region has a higher P-type concentration than the fourth diffusion region. With this, it becomes possible to prevent the power source voltage of the internal circuit from deteriorating significantly and triggering circuit malfunction.

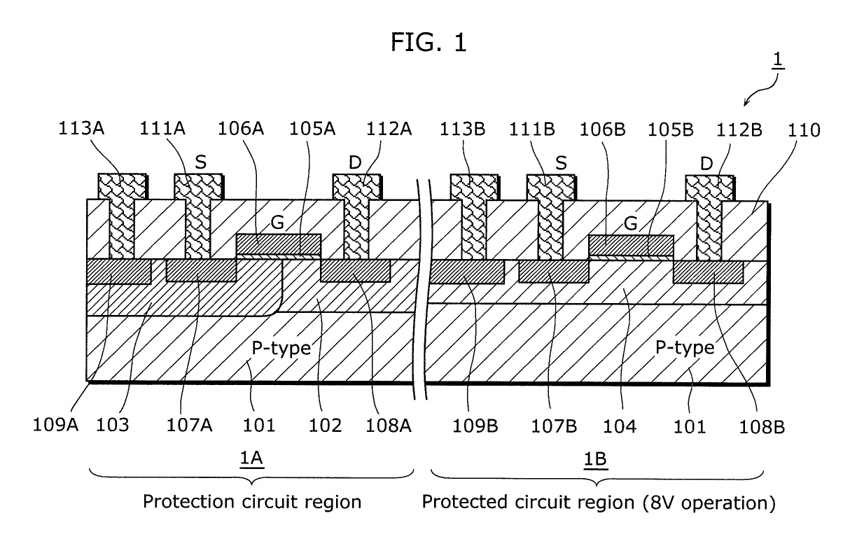

Hereinafter, a first embodiment of the present invention shall be described with reference to the FIG. 1 to FIG. 3.

FIG. 1 is a structural cross-sectional view showing the main parts of an ESD protection element and a protected element included in a semiconductor device in the first embodiment of the present invention. A semiconductor device 1 shown in the figure includes an ESD protection element 1A and a protected element 1B. The ESD protection element 1A and the protected element 1B are formed on a continuous P-type Si substrate 101.

The ESD protection element 1A is a MOS transistor formed in a protection circuit region of the P-type Si substrate 101 and includes the P-type Si substrate 101, a gate insulating film 105A, a gate electrode 106A, a source electrode 111A, a drain electrode 112A, a substrate contact electrode 113A, and an inter-layer insulating film 110. The ESD protection element 1A functions as a protection circuit included in the semiconductor device 1.

The protected element 1B is a MOS transistor formed in a protected circuit region of the P-type Si substrate 101 and includes the P-type Si substrate 101, a gate insulating film 105B, a gate electrode 106B, a source electrode 111B, a drain electrode 112B, a substrate contact electrode 113B, and the inter-layer insulating film 110. The protected element 1B is a circuit element making up an internal circuit included in the semiconductor device 1.

The protected element 1B in the present embodiment is configured of, for example, an 8V operating system circuit element (hereafter denoted as normal-withstand voltage element). The ESD protection element 1A protects the drain of the normal-withstand voltage element against voltage surge.

Here, the 8V operating system circuit refers to a circuit for which the operating power source voltage for circuit operation is 8V. Furthermore, operating power source voltage refers to the power source voltage at which normal operation of a circuit is guaranteed.

A medium-concentration P-type diffusion region 102, a high-concentration P-type diffusion region 103, a low-concentration P-type diffusion region 104, source N-type diffusion regions 107A and 107B, drain N-type diffusion regions 108A and 108B, and substrate contact P-type diffusion regions 109A and 109B are formed in the P-type Si substrate 101.

The P-type Si substrate 101 is a semiconductor substrate of a second conductivity type, and the impurity elemental concentration of its original region is, for example, approximately 1E14 cm⁻³. Here, the original region refers to a low-concentration, second conductivity-type region formed uniformly on the entirety of the aforementioned semiconductor substrate before hand, prior to forming the semiconductor device in the present invention.

The medium-concentration P-type diffusion region 102, which is a seventh diffusion region of the second conductivity type, is a P-type diffusion region formed from under the drain N-type diffusion region 108A to under part of the gate electrode 106A and covers the drain N-type diffusion region 108A within the P-type Si substrate 101.

The gate electrodes 106A and 106B, which are a first gate electrode and a second gate electrode, respectively, are formed above the P-type Si substrate 101 so as to sandwich the gate insulating films 105A and 105B, respectively. The gate electrode 106A is grounded. The source electrode 111A and the drain electrode 112A, which are a second electrode and a first electrode, respectively, are formed on the P-type Si substrate 101, at opposite sides of, but apart from, the gate electrode 106A. The source electrode 111A is grounded. The source electrode 111B and the drain electrode 112B, which are a fourth electrode and a third electrode, respectively, are formed on the P-type Si substrate 101, at opposite sides of, but apart from, the gate electrode 106B. The substrate contact electrode 113A is a grounded fifth electrode. The substrate contact electrodes 113A and 113B are formed on the P-type Si substrate 101, near the source electrodes 111A and 111B, respectively.

The source N-type diffusion region 107A is a first diffusion region of a first conductivity-type. The source N-type diffusion regions 107A and 107B are formed within the P-type Si substrate 101 and are in contact with the source electrode 111A and 111B, respectively.

The drain N-type diffusion regions 108A and 108B, which are a sixth diffusion region of the first conductivity-type and a third diffusion region of the first conductivity-type, respectively, are formed within the P-type Si substrate 101 and are in contact with the source electrode 111A and 111B, respectively.

The substrate contact P-type diffusion region 109A is a fifth diffusion region of the second conductivity-type. The substrate contact P-type diffusion regions 109A and 109B are formed near to or in contact with the source N-type diffusion regions 107A and 107B, respectively.

The high-concentration P-type diffusion region 103, which is a second diffusion region of the second conductivity type, is a P-type diffusion region formed from under the source N-type diffusion region 107A to under part of the gate electrode 106A and covers the source N-type diffusion region 107A and the substrate contact P-type diffusion region 109A within the P-type Si substrate 101. The P-type impurity elemental concentration of the high-concentration P-type diffusion region 103 is, for example, approximately 2E16 to 2E17 cm⁻³. The high-concentration P-type diffusion region 103 has a higher P-type impurity concentration than the original region of the P-type Si substrate 101.

The high-concentration P-type diffusion region 103 and the medium-concentration P-type diffusion region 102 are in contact below the gate electrode 106A.

The low-concentration P-type diffusion region 104, which is a fourth diffusion region of the second conductivity-type, is formed within the P-type Si substrate 101. Furthermore, the low-concentration P-type diffusion region 104 is a P-type diffusion region formed continuously from under the substrate contact P-type diffusion region 1096 to the drain N-type diffusion region 108B, and covers the substrate contact P-type diffusion region 1096, the source N-type diffusion region 107B, and the drain N-type diffusion region 108B.

Here, the high-concentration P-type diffusion region 103 and the medium-concentration P-type diffusion region 102 included in the ESD protection element 1A have a higher P-type impurity elemental concentration than the low-concentration P-type diffusion region 104 included in the protected element 1B.

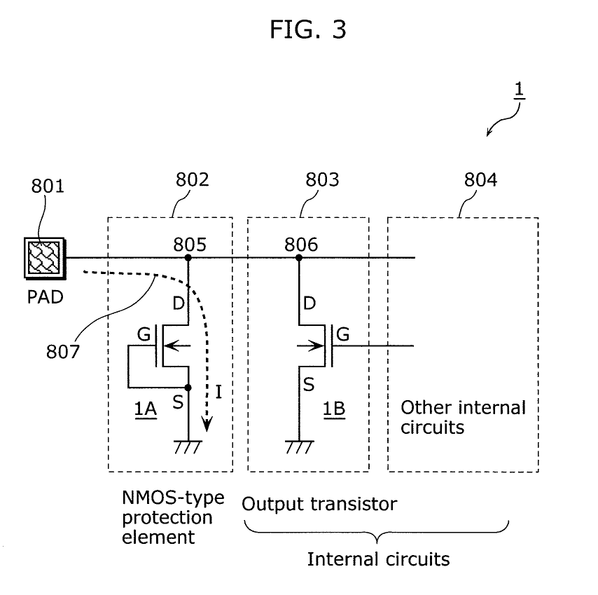

Furthermore, the ESD protection element 1A and the protected element 1B are connected to an external connecting terminal and to other internal circuits via the gate electrodes 106A and 106B, the source electrodes 111A and 111B, the drain electrodes 112A and 112B, and the substrate contact electrodes 113A and 113B, which are formed in the inter-layer insulating film 110. With regard to this connection, a specific example shall be described using FIG. 3.

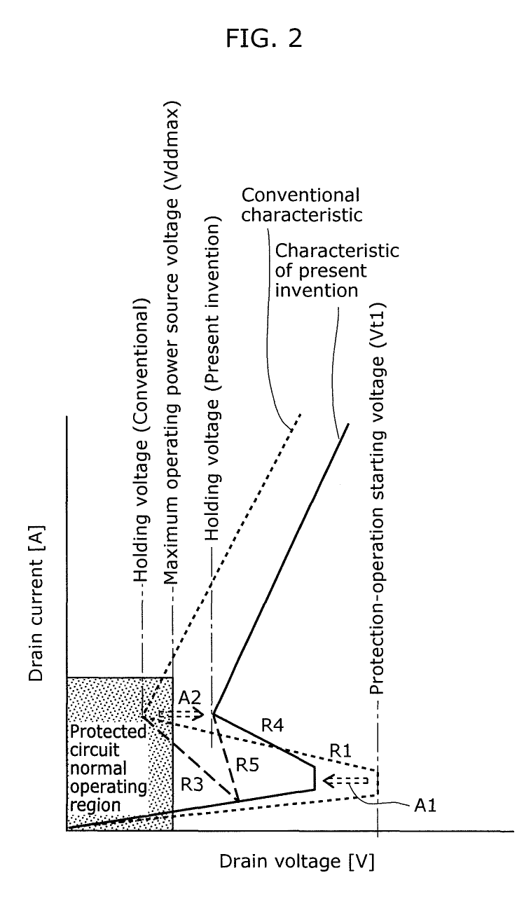

FIG. 2 is a graph showing a comparison of the discharging characteristics of the present invention and the conventional ESD protection circuit. Furthermore, FIG. 3 is a typical circuit configuration diagram showing the connection relationship between the protection circuit and the internal circuits. Furthermore, since the ESD protection element 1A is formed simultaneously in the manufacturing process of the internal circuits in the semiconductor device in the present invention, the protection circuit and the internal circuits shall be described in relation with each other.

In the graph shown in FIG. 2, the horizontal axis denotes the drain terminal voltage of the ESD protection element 1A, and the vertical axis denotes the drain current flowing from the drain to the source of the ESD protection element 1A. Furthermore, in the circuit configuration in this case, the drain terminal is connected to a pad 801 (see FIG. 3) which is a terminal for connection with the outside.

When a surge voltage is applied to the drain terminal of the ESD protection element 1A from the outside, the drain terminal voltage increases abruptly. Subsequently, when the surge voltage reaches the protection-operation starting voltage (hereafter denoted as Vt1) an NPN-type parasitic bipolar transistor formed by the source N-type diffusion region 107A, the drain N-type diffusion region 108A, and the P-type diffusion regions formed therebetween becomes conductive. At this time, current flows from the drain terminal towards the source terminal and, due to the snapback phenomenon, the drain terminal voltage deteriorates up to a holding voltage (hereafter denoted as Vh) which is the minimum value of voltage generated between the drain and the source. Subsequently, the protected element 1B of the internal circuit connected to the drain terminal can be protected by transition to the main discharging operation.

Since Vt1 is the voltage at which the ESD protection element 1A starts the protection operation, Vt1 must be lower than the actual value of the drain withstand voltage of the protected element 1B.

In general, the drain withstand voltage of a protected element is dependent on the reverse withstand voltage of a P-N junction formed in the diffusion regions below the drain electrode. The reverse withstand voltage increases as the P-type concentration and the N-type concentration in the respective P-type region and N-type region making up the P-N junction decrease.

In the present embodiment, the drain withstand voltage of the protected element 1B is dependent on the reverse withstand voltage of a P-N junction formed in the interface between the drain N-type diffusion region 108B and the low-concentration P-type diffusion region 104.

On the other hand, the Vt1 of the ESD protection element 1A is dependent on the reverse withstand voltage of a P-N junction formed in the interface between the drain N-type diffusion region 108A and the P-type diffusion region in contact therewith.

From the function and manufacturing perspectives, since the N-type impurity concentration is set identically for the drain N-type diffusion regions 108A and 108B, setting the P-type concentration of the P-type diffusion region contacting the drain N-type diffusion regions 108A to be higher than that of the low-concentration P-type diffusion region 104 allows Vt1 to be set lower than the withstand voltage of the protected element 1B.

Therefore, the medium-concentration P-type diffusion region 102, which is the P-type diffusion region contacting the drain N-type diffusion region 108A, is set to have a higher P-type concentration than the low-concentration P-type diffusion region 104 in the protected element 1B.

With this, in the case where the drain side is an output transistor having the same structure, it is possible to cause the ESD protection element 1A to operate before the protected element 1B becomes conductive, and thus the internal circuit can be appropriately protected against surge voltage from the outside.

It should be noted that it is preferable that the medium-concentration P-type diffusion region 102 of the ESD protection element 1A is set to have P-type concentration that is two or more times higher than that of the low-concentration P-type diffusion region 104 of the protected element 1B. With this, it becomes possible to implement a semiconductor device that executes a more reliable protection operation which takes into account variation factors of the diffusion regions such as variations in concentration, and so on. To describe this using the discharging characteristics shown in FIG. 2, increasing the P-type concentration of the medium-concentration P-type diffusion region 102 of the ESD protection element 1A makes it possible to cause Vt1 to shift to the A1 direction.

In contrast, Vh is the minimum voltage attained by the voltage of the drain electrode 112A when the ESD protection element goes into the protection operation. As such, when the ESD protection element 1A is embedded in the same semiconductor substrate together with the other circuit elements, it is necessary to set Vh high to prevent malfunctioning of the protected element due to the increase in substrate current caused by the operation of surrounding circuits or the increase in substrate potential due to noise.

To describe using the discharging characteristics shown in FIG. 2, it is necessary to prevent Vh from deteriorating up to the normal operating region of the protected circuit due to the parasitic bipolar transistor of the ESD protection element following the characteristic R3. In other words, it is preferable that Vh does not go below the maximum operating power source voltage of the protected circuit. Here, the maximum operating power source voltage is the highest power source voltage at which normal operation of the internal circuits including the protected circuit is guaranteed. The maximum operating power source voltage of a protected circuit is dependent on the drain withstand voltage of the protected element. As previously described, the drain withstand voltage of a protected element is dependent on the reverse withstand voltage of the P-N junction formed in the diffusion regions below the drain electrode. Therefore, the maximum operating power source voltage is dependent on the reverse withstand voltage of such P-N junction.

With the conventional semiconductor device, when a protected element and a protection element which have an FET structure are formed on the same substrate, there are cases where the Vh when Vt1 of the protection element is merely set lower than the withstand voltage of the protected element and the parasitic bipolar transistor is in ON deteriorates up to within the region of the power source voltage at which the protected circuit operates normally. In this case, the power source voltage of the protected circuit deteriorates up to Vh and thus the protected circuit malfunctions. With the protection circuit included in the conventional semiconductor device, since there is no perspective for controlling Vh, the concentration in the P-type region formed below the source electrode and the gate electrode of the ESD protection element is set to be the same as or lower than the concentration of the P-type region below the drain electrode of the protected element.

On the other hand, with the semiconductor device in the embodiments of the present invention, the P-type concentration of the high-concentration P-type diffusion region 103 is set higher than that of the low-concentration P-type diffusion region 104 which is a factor for determining the maximum operating power source voltage of the protected element. To describe using the graph shown in FIG. 2, the maximum operation power source voltage is represented as the upper-limit value of the voltage of the protected circuit normal operating region. With this, the base resistance of the parasitic bipolar transistor formed between the drain and the source of the ESD protection element 1A decreases relatively, and the increase of the base potential with respect to drain voltage, substrate current, and power source noise can be suppressed. With this, the Vh when the parasitic bipolar transistor is ON can be improved compared to the conventional protection circuit in which the Vt1 of the protection circuit is merely set lower than the withstand voltage of the protected device.

It should be noted that although it is preferable that, with the high-concentration P-type diffusion region 103 of the ESD protection element 1A, the P-type concentration is set such that Vh does not go below the maximum operating power source voltage of the protected circuit as previously described, it is further preferable that Vh be higher than such maximum operating power source voltage by a predetermined margin in order to implement reliable malfunction avoidance for the protected circuit. Specifically, it is preferable that the high-concentration P-type diffusion region 103 is set to have a P-type concentration that is, for example, two or more times higher than that of the low-concentration P-type diffusion region 104. With this, it becomes possible to implement a semiconductor device that executes a more reliable protection operation which takes into account variation factors of the diffusion regions such as variations in concentration, and so on.

It should be noted that, in the present embodiment, the substrate contact P-type diffusion region 109A is formed near the source N-type diffusion region 107A. With this, majority of the generated substrate current passes through the high-concentration P-type diffusion region 103 and passes through the current path to the substrate contact P-type diffusion region 109A which has a lower resistance than the current path to the source N-type diffusion region 107A. As such, an increase in the base potential of the parasitic bipolar transistor can be suppressed. This means that the conductive state is not realized unless the drain voltage becomes a higher potential, and this means increasing Vh. Therefore, power source voltage deterioration and circuit malfunctioning of the protected circuit can be prevented.

With the above-described configuration, the semiconductor device in the present embodiment can prevent the power source voltage of the internal circuit from deteriorating significantly and triggering circuit malfunctioning. In the graph shown in FIG. 2, conventionally, when the parasitic bipolar transistor is ON, the characteristic R1 is followed in the case where a surge voltage from the outside is applied to the drain terminal, and the characteristic R3 is followed in a case brought about by the previously described increase of the substrate current and the substrate potential even during normal operation, and as a result, Vh deteriorates up to the normal operating region of the protected circuit. In contrast, with the present invention, it is shown that when the parasitic bipolar transistor is ON, a path such as that in characteristic R4 or R5 is followed and, as a result, Vh is improved in the A2 direction and does not deteriorate up to the normal operating region of the protected circuit.

FIG. 3 shows an example of the circuit configuration of the ESD protection element 1A and the protected element 1B, and shows that the pad 801 which is a terminal for connection to the outside is connected to a drain terminal 805 of the NMOS-type ESD protection element 1A (ESD protection circuit 802). Furthermore, the drain terminal 805 is connected to a drain terminal 806 of the protected element 1B (protected circuit 803) which is an output transistor, and to other internal circuits 804.

With this configuration, when a surge voltage is applied to the pad 801 the discharge current can, before flowing into the protected circuit 803 of the internal circuit, be allowed to escape to a ground line as a discharge current (I) 807 passing through the ESD protection circuit 802.

In the present embodiment, the impurity elemental concentration of the low-concentration P-type diffusion region 104 of the protected element 1B is, for example, approximately 3E16 cm⁻³. In contrast, in order to set the Vt1 of the ESD protection element 1A to the value having the aforementioned condition, ion injection and heat treatment are adjusted so that the impurity elemental concentration of the medium-concentration P-type diffusion region 102 becomes, for example, approximately 7E16 cm⁻³. Furthermore, in order to set the Vh of the ESD protection element 1A to the value having the aforementioned condition, ion injection and heat treatment are adjusted so that the impurity elemental concentration of the high-concentration P-type diffusion region 103 becomes, for example, approximately 9E16 cm⁻³.

It should be noted that the aforementioned value for the impurity elemental concentration of each diffusion region represents a relative value for an arbitrary reference value such as the concentration of the original region of the semiconductor substrate forming the internal circuit, for example, and does not represent an absolute value for solving the problem.

By adopting such a configuration, Vh can be set higher than the maximum operating power source voltage since the source of the ESD protection element 1A and the substrate contact periphery assume a low resistance, and thus the increase of the substrate potential can be suppressed. In addition, Vt1 can be set lower than the drain withstand voltage of the protected element 1B and higher than the maximum operating power source voltage.

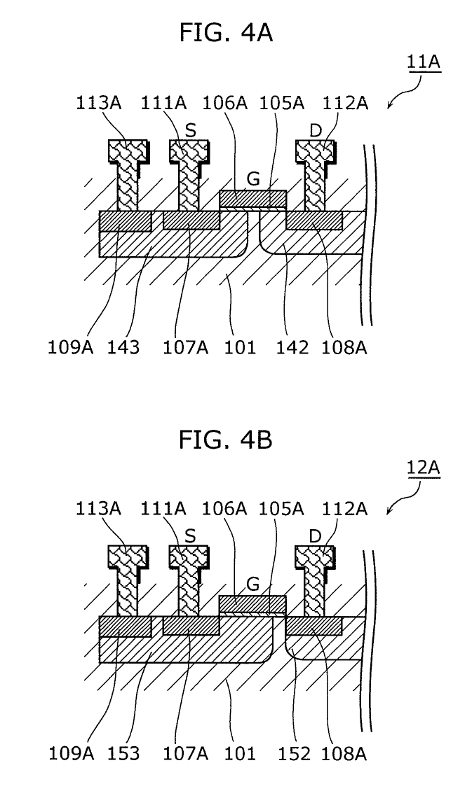

FIG. 4A and FIG. 4B are structural cross-sectional views of ESD protection elements representing a first modification and a second modification of the semiconductor device in the first embodiment of the present invention, respectively. FIG. 4A and FIG. 4B both show diffusion regions of respective ESD protection elements. ESD protection elements 11A and 12A shown in FIG. 4A and FIG. 4A, respectively, are different compared to the ESD protection element 1A shown in FIG. 1 only in the configuration of the diffusion regions within the P-type Si substrate 101. Description of points that are the same as in the ESD protection element 1A shown in FIG. 1 shall be omitted, and only the points of difference shall be described hereafter.

First, the first modification of the semiconductor device in the first embodiment of the present invention shown in FIG. 4A shall be described.

A high-concentration P-type diffusion region 143, which is a second diffusion region of the second conductivity type, is a P-type diffusion region formed from under the source N-type diffusion region 107A to under part of the gate electrode 106A, and covers the source N-type diffusion region 107A and the substrate contact P-type diffusion region 109A within the P-type Si substrate 101. The P-type impurity elemental concentration of the high-concentration P-type diffusion region 143 is approximately 2E16 to 2E17 cm⁻³. The high-concentration P-type diffusion region 103 has a higher P-type impurity concentration than the original region of the P-type Si substrate 101.

A medium-concentration P-type diffusion region 142, which is a seventh diffusion region of the second conductivity type, is a P-type diffusion region formed from under the drain N-type diffusion region 108A to under part of the gate electrode 106A, and covers the drain N-type diffusion region 108A within the P-type Si substrate 101.

The high-concentration P-type diffusion region 143 and the medium-concentration P-type diffusion region 142 are not in contact below the gate electrode 106A, having the original region of the P-type Si substrate 101 disposed between them.

Since the medium-concentration P-type diffusion region 142 covers the drain N-type diffusion region 108A, the Vt1 of the ESD protection device 11A is determined according to the P-N junction formed by these two regions. Therefore, the medium-concentration P-type diffusion region 142 need not be in contact with the high-concentration P-type diffusion region 143 below the gate electrode 106A.

Next, the second modification of the semiconductor device in the first embodiment of the present invention shown in FIG. 4B shall be described.

A high-concentration P-type diffusion region 153, which is a second diffusion region of the second conductivity type, is a P-type diffusion region formed from under the source N-type diffusion region 107A to under part of the gate electrode 106A, and covers the source N-type diffusion region 107A and the substrate contact P-type diffusion region 109A within the P-type Si substrate 101. The P-type impurity elemental concentration of the high-concentration P-type diffusion region 153 is approximately 2E16 to 2E17 cm⁻³. The high-concentration P-type diffusion region 103 has a higher P-type impurity concentration than the original region of the P-type Si substrate 101.

A medium-concentration P-type diffusion region 152, which is a seventh diffusion region of the second conductivity type, is a P-type diffusion region formed beneath the drain N-type diffusion region 108A within the P-type Si substrate 101, and is in contact with the drain N-type diffusion region 108A. Here, the medium-concentration P-type diffusion region 152 is not in contact with the gate-side side surface of the drain N-type diffusion region 108A.

The high-concentration P-type diffusion region 153 and the medium-concentration P-type diffusion region 152 are not in contact below the gate electrode 106A, having the original region of the P-type Si substrate 101 disposed between them.

The Vt1 of the ESD protection element 12A is dependent on the reverse withstand voltage of the P-N junction formed below the drain electrode 112A, and such reverse withstand voltage increases as the P-type concentration and the N-type concentration in the respective P-type region and the N-type region making up such P-N junction decrease. In the case of the present modification, such P-N junction includes the P-N junction in the interface between the drain N-type diffusion region 108A and the medium-concentration P-type diffusion region 152, and the P-N junction in the interface between the drain N-type diffusion region 108A and the P-type Si substrate 101. In this case, there is a significant concentration difference between the P-type region and the N-type region for the P-N junction in the interface between the drain N-type diffusion region 108A and the medium-concentration P-type diffusion region 152, and the Vt1 of the ESD protection element 12A is determined according to this junction. Specifically, since the medium-concentration P-type diffusion region 152 is formed apart from the high-concentration P-type diffusion region 153, Vt1 is not affected by the high-concentration P-type diffusion region 153. Therefore, even with the present modification, the high-concentration P-type diffusion region 153 which affects Vh and the medium-concentration P-type diffusion region 152 which affects Vt1 can be controlled independently, and thus Vt1 and Vh can be set separately.

### Second Embodiment

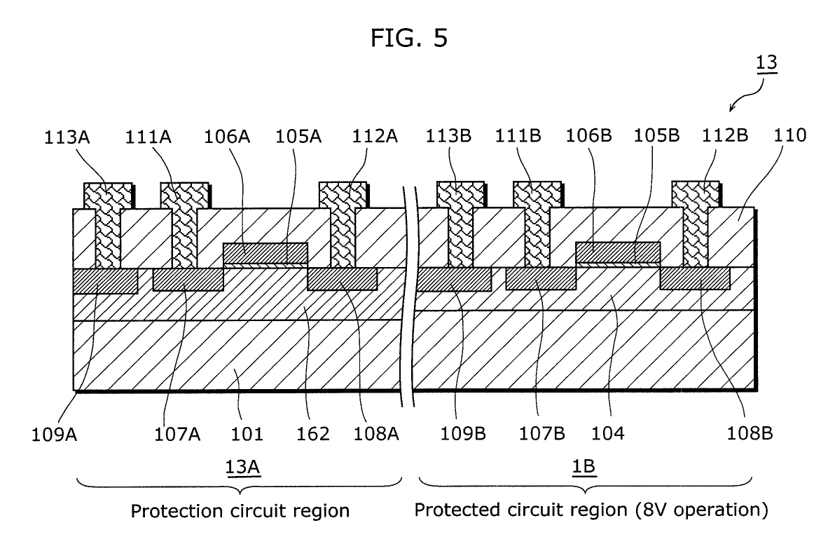

FIG. 5 is a structural cross-sectional view showing the main parts of an ESD protection element and a protected element included in a semiconductor device in a second embodiment of the present invention. A semiconductor device 13 shown in the figure includes an ESD protection element 13A and the protected element 1B. The ESD protection element 13A and the protected element 1B are formed on the continuous P-type Si substrate 101. The semiconductor device in the present embodiment is different compared to the semiconductor device 1 shown in FIG. 1 only in the configuration of the diffusion regions of the ESD protection element. Description of points that are the same as in the ESD protection element 1A shown in FIG. 1 shall be omitted, and only the points of difference shall be described hereafter.

In the present embodiment, as shown in FIG. 5, a P-type diffusion region 162 within the P-type Si substrate 101 and extending from the source electrode 111A and the drain electrode 112A is set to have the same impurity elemental concentration, and this becomes an effective means when the Vt1 and Vh of the ESD protection element 13A can be set to a desired value using the same impurity elemental concentration.

The P-type diffusion region 162, which is a second diffusion region of the second conductivity-type and a seventh diffusion region of the second conductivity type, is formed within the P-type Si substrate 101. Furthermore, the P-type diffusion region 162 is a P-type diffusion region formed homogeneously from under the substrate contact P-type diffusion region 109A to under the drain N-type diffusion region 108A, and covers the source N-type diffusion region 107A, the drain N-type diffusion region 108A, and the substrate contact P-type diffusion region 109A.

Here, the P-type diffusion region 162 of the ESD protection element 13A has a higher impurity elemental concentration than the low-concentration P-type diffusion region 104 of the protected element 1B. As the impurity elemental concentration of the P-type diffusion region 162, the impurity elemental concentration of the medium-concentration P-type diffusion region 102 in the first embodiment is suitable, and thus ion injection and heat treatment are adjusted so that the impurity elemental concentration becomes, for example, 7E16 cm⁻³.

Furthermore, as the impurity elemental concentration of the P-type diffusion region 162, the impurity elemental concentration of the high-concentration P-type diffusion region 103 in the first embodiment is suitable, and thus ion injection and heat treatment are adjusted so that the impurity elemental concentration becomes, for example, 9E16 cm⁻³.

In the setting of the concentration of the P-type diffusion region 162 in the manufacturing process of the ESD protection element in the present invention, when the concentration is to be set to that of the impurity elemental concentration of the medium-concentration P-type diffusion region 102, the concentration is controlled solely by an additional process of ion injection. In contrast, when the concentration is to be set to the impurity elemental concentration of the high-concentration P-type diffusion region 103, a P-type region of higher concentration can be formed by controlling the concentration using a combination of the ion injection in the existing process used in the manufacturing process of the protected element 1B and an additional ion injection.

It should be noted that it is preferable that the P-type diffusion region 162 has a high concentration that is two or more times that of the low-concentration P-type diffusion region 104 of the protected element 1B. With this, it becomes possible to implement a semiconductor device that executes a more reliable protection operation which takes into account variation factors of the diffusion regions such as variations in concentration, and so on.

In the present embodiment, the impurity elemental concentration of the low-concentration P-type diffusion region 104 of the protected element 1B is set to approximately 3E16 cm⁻³. Thus, in order to set the Vt1 and the Vh of the ESD protection element 1A to a desired value, ion injections are combined and, in addition, heat treatment is adjusted so that the impurity elemental concentration of the P-type diffusion region 162 becomes approximately 7E16 cm⁻³ or 9E16 cm⁻³.

It should be noted that the aforementioned set value for the impurity elemental concentration represents a relative value for an arbitrary reference value, and does not represent an absolute value for solving the problem.

With the above-described configuration, the respective P-type diffusion regions under the source electrode and the drain electrode of the ESD protection element 13A can be simultaneously set to have a high concentration, that is, to have low resistance, and thus Vh and Vt1 can be controlled simultaneously.

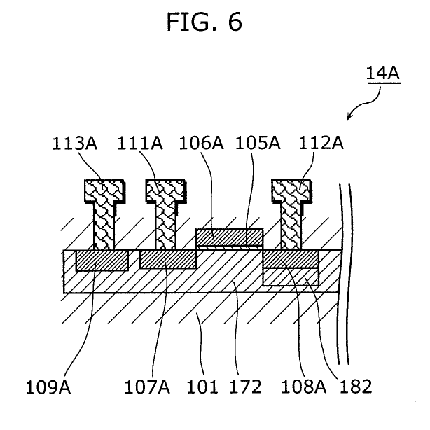

FIG. 6 is a structural cross-sectional view of an ESD protection element representing a modification of the semiconductor device in the second embodiment of the present invention. FIG. 6 shows the diffusion regions of the ESD protection element. An ESD protection element 14A shown in FIG. 6 is different compared to the ESD protection element 13A shown in FIG. 5 only in the configuration of the diffusion regions within the P-type Si substrate 101. Description of points that are the same as with the ESD protection element shown in FIG. 5 shall be omitted and only the points of difference shall be described hereafter.

A P-type diffusion region 172, which is a second diffusion region of the second conductivity-type, is formed within the P-type Si substrate 101. Furthermore, the P-type diffusion region 172 is a P-type diffusion layer formed homogeneously from under the substrate contact P-type diffusion region 109A to under the drain N-type diffusion region 108A, and covers the source N-type diffusion region 107A and the substrate contact P-type diffusion region 109A and is in contact with the drain N-type diffusion region 108A.

Here, the P-type diffusion region 172 of the ESD protection element 14A has a higher impurity elemental concentration than the low-concentration P-type diffusion region 104 of the protected element 1B.

A P-type diffusion region 182, which is a seventh diffusion region of the second conductivity type, is a P-type diffusion region formed within the P-type Si substrate 101, and is in contact with the lower surface of the drain N-type diffusion region 108A.

Here, the P-type diffusion region 182 of the ESD protection element 14A has a higher impurity elemental concentration than the P-type diffusion region 172.

By forming of the P-type diffusion region 182 within the P-type diffusion region 172 which is formed homogeneously from under the substrate contact P-type diffusion region 109A to under the drain N-type diffusion region 108A, Vh and Vt1 can be controlled independently.

### Third Embodiment

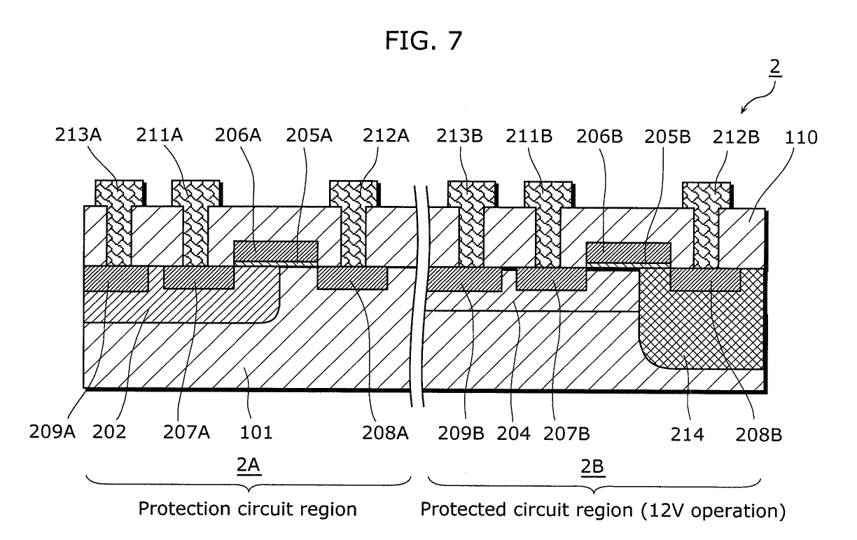

FIG. 7 is a structural cross-sectional view showing the main parts of an ESD protection element and a protected element included in a semiconductor device in a third embodiment of the present invention. A semiconductor device 2 shown in the figure includes an ESD protection element 2A and the protected element 2B. The ESD protection element 2A and the protected element 2B are formed on the continuous P-type Si substrate 101. The semiconductor device 2 in the present embodiment is different compared to the semiconductor device 1 shown in FIG. 1 only in the configuration of the diffusion regions of the ESD protection element and the protected element. Description of points that are the same as in the ESD protection element 1A shown in FIG. 1 shall be omitted, and only the points of difference shall be described hereafter.

The protected element 2B in the present embodiment is used in a circuit operating at an intermediate voltage and is configured of, for example, a 12V operating system circuit element (hereafter denoted as intermediate-withstand voltage element). The ESD protection element 2A protects the drain of the intermediate-withstand voltage element against voltage surge.

In the protected element 2B, which is an intermediate-withstand voltage element, a drain N-type diffusion region 208B is formed inward of a low concentration N-type diffusion region 214, and the drain withstand voltage thereof is enhanced over that of a normal element. For example, compared to the approximately 15V drain withstand voltage of the normal-withstand voltage element which operates at 8V, the drain withstand voltage of the intermediate-withstand voltage element is approximately 40 to 48V.

It should be noted that in the present embodiment, since the ESD protection element 2A is formed simultaneously in the manufacturing process of the protected element 2B, both shall be described in relation with each other in the subsequent description.

The ESD protection element 2A is a MOS transistor formed in a protection circuit region of the P-type Si substrate 101 and includes the P-type Si substrate 101, a gate insulating film 205A, a gate electrode 206A, a source electrode 211A, a drain electrode 212A, a substrate contact electrode 213A, and the inter-layer insulating film 110. The ESD protection element 2A functions as a protection circuit included in the semiconductor device 2.

The protected element 2B is a MOS transistor formed in a protected circuit region of the P-type Si substrate 101 and includes the P-type Si substrate 101, a gate insulating film 205B, a gate electrode 206B, a source electrode 211B, a drain electrode 212B, a substrate contact electrode 213B, and the inter-layer insulating film 110. The protected element 2B is a circuit element making up an internal circuit included in the semiconductor device 2.

A medium-concentration P-type diffusion region 202, a low-concentration P-type diffusion region 204, source N-type diffusion regions 207A and 207B, drain N-type diffusion regions 208A and 208B, and substrate contact P-type diffusion regions 209A and 209B are formed in the P-type Si substrate 101.

The P-type Si substrate 101 is a semiconductor substrate of a second conductivity type, and the impurity elemental concentration of its original region in which the above-mentioned diffusion regions are not formed is, for example, approximately 1E14 cm⁻³.

The medium-concentration P-type diffusion region 202, which is a second diffusion region of the second conductivity type, is a P-type diffusion region formed from under the source N-type diffusion region 207A to under part of the gate electrode 206A, and covers the source N-type diffusion region 207A and the substrate contact P-type diffusion region 209A within the P-type Si substrate 101. It should be noted that the medium-concentration P-type diffusion region 202 may also be a high-concentration P-type diffusion region. The medium-concentration P-type diffusion region 202 has a higher P-type impurity concentration than the original region of the P-type Si substrate 101.

The low-concentration P-type diffusion region 204, which is a fourth diffusion region of the second conductivity type, is a P-type diffusion region formed from under the substrate contact P-type diffusion region 209B to under part of the gate electrode 206B, and covers the substrate contact P-type diffusion region 209B and the source N-type diffusion region 207B within the P-type Si substrate 101.

Here, the medium-concentration P-type diffusion region 202 of the ESD protection element 2A has a higher P-type impurity elemental concentration than the low-concentration P-type diffusion region 204 included in the protected element 2B.

Furthermore, in the protected element 2B, the low concentration N-type diffusion region 214 is formed below and in the periphery of the drain N-type diffusion region 208B. The low concentration N-type diffusion region 214 and the low-concentration P-type diffusion region 204 are in contact below the gate electrode 2066.

The above-described configuration is one example of an intermediate-withstand voltage element having an enhanced drain withstand voltage. As previously described, in general, the drain withstand voltage of a protected element is dependent on the reverse withstand voltage of a P-N junction formed in the diffusion regions below the drain electrode. The reverse withstand voltage increases as the P-type concentration and the N-type concentration in the respective P-type region and N-type region making up the P-N junction decrease. In the present embodiment, the drain withstand voltage of the protected element 2B is dependent on the reverse withstand voltage of the P-N junction formed in the interface between the low-concentration N-type diffusion region 214 and the low-concentration P-type diffusion region 204.

It should be noted that, in the same manner as in the ESD protection element 1A and the protected element 1B in the first embodiment, the ESD protection element 2A and the protected element 2B are connected to an external connecting terminal and to other internal circuit elements.

With the intermediate-voltage system circuit in the present embodiment, the maximum operating power source voltage is 12V, and thus there is sufficient leeway compared to the 40 to 48V drain withstand voltage of the protected element 2B. Therefore, with the ESD protection element 2A, increasing, instead of decreasing, the drain withstand voltage of the ESD protection element itself allows the breakdown-tolerance of the ESD protection element 2A itself to be enhanced, in the same manner as the ESD protection element 1A which supports the normal-withstand voltage element. Consequently, the P-type region below the drain electrode 212A of the ESD protection element 2A is implemented by using the concentration of the original region of the P-type Si substrate 101 which is even lower than that of the low concentration P-type diffusion region.

On the other hand, there is a significant relationship between the Vh of the ESD protection element 2A and the impurity concentration in the P-type region below and in the periphery below the source electrode 211A. When setting the concentration of the P-type region to that of the medium-concentration P-type diffusion region 202, the concentration setting is controlled solely by ion injection in an additional process. In contrast, when such P-type region is set to a high-concentration P-type diffusion region, controlling the concentration setting through a combination of the ion injection in the existing process and ion injection in an additional process allows for the formation of a P-type region of higher concentration.

It should be noted that it is preferable that the medium-concentration P-type diffusion region 202 of the ESD protection element 2A is set to have a high concentration that is two or more times higher than that of the low-concentration P-type diffusion region 204 of the protected element 2B. With this, it becomes possible to implement a semiconductor device that executes a more reliable protection operation which takes into account variation factors of the diffusion regions such as variations in concentration, and so on.

In the present embodiment, the impurity elemental concentration of the low-concentration P-type diffusion region 204 of the protected element 2B is, for example, approximately 3E16 cm⁻³. In this case, in order to improve the Vh of the ESD protection element 2A, ion injection is performed and heat treatment is adjusted so that the impurity elemental concentration of the medium-concentration P-type diffusion region 202 becomes approximately 7E16 cm⁻³. Alternatively, in order for the medium-concentration P-type diffusion region 202 to become a high-concentration P-type diffusion region, combination of ion injections and, in addition, adjustment of heat treatment is performed in order for the impurity elemental concentration to be, for example, approximately 9E16 cm⁻³.

It should be noted that the aforementioned impurity elemental concentration represents a relative value for an arbitrary reference value, and does not represent an absolute value for solving the problem.

With the semiconductor device in the embodiments of the present invention, the P-type concentration of the medium-concentration P-type diffusion region 202 is set higher than that of the low-concentration P-type diffusion region 204 which is a factor for determining the maximum operating power source voltage (12V) of the protected element 2B. With this, the base resistance of the parasitic bipolar transistor formed between the drain and the source of the ESD protection element 2A decreases relatively, and the increase of the base potential with respect to drain voltage, substrate current, and power source noise can be suppressed. With this, the Vh when the parasitic bipolar transistor is ON can be improved compared to that in the conventional protection circuit in which the Vt1 of the protection circuit is merely set lower than the withstand voltage of the protected device.

It should be noted that, in the present embodiment, the substrate contact P-type diffusion region 209A is formed near the source N-type diffusion region 207A. With this, majority of the generated substrate current passes through the medium-concentration P-type diffusion region 202 and passes through the current path to the substrate contact P-type diffusion region 209A which has lower resistance than the current path to the source N-type diffusion region 207A. As such, an increase in the base potential of the parasitic bipolar transistor can be suppressed. This means that the conductive state is not realized unless the drain voltage becomes a higher potential, and thus Vh is enhanced. Therefore, power source voltage deterioration and circuit malfunctioning of the protected circuit can be prevented.

With the above-described configuration, the semiconductor device in the present embodiment can prevent the power source voltage of the internal circuit from deteriorating significantly and triggering circuit malfunctioning, even when the protected element is an intermediate-withstand voltage element.

### Fourth Embodiment

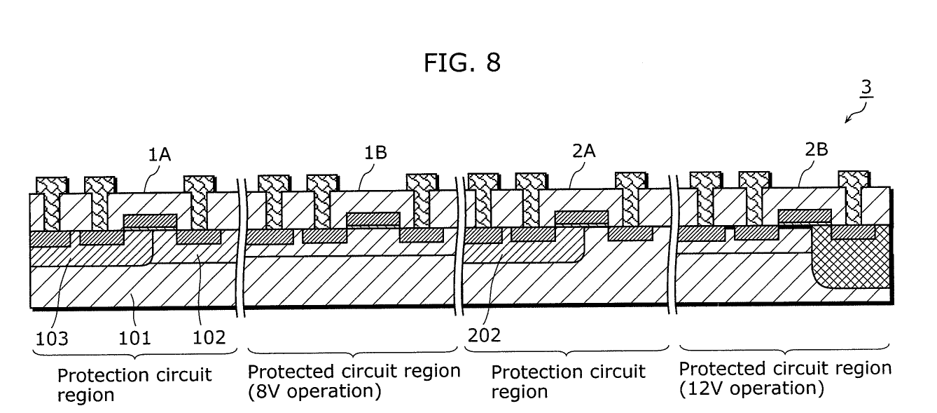

FIG. 8 is a structural cross-sectional view showing the main parts of an ESD protection element and a protected element included in a semiconductor device in a fourth embodiment of the present invention. A semiconductor device 3 shown in the figure includes the ESD protection elements 1A and 2A and the protected elements 1B and 2B. The semiconductor device 3 shown in FIG. 8 includes a normal-withstand voltage element and an intermediate-withstand voltage element each provided with an ESD protection element. Specifically, the cross-sectional view of the semiconductor device 3 shows a structure for efficiently forming the ESD protection element 1A and the ESD protection element 2A in the same manufacturing process when a normal-withstand voltage element and an intermediate-withstand voltage element are deposited together on the same semiconductor substrate.

Description of the respective configurations of the ESD protection elements 1A and 2A, and the protected elements 1B and 2B shall be omitted, and only the points of difference with the first to third embodiments shall be described hereafter.

The ESD protection elements 1A and 2A, and the protected elements 1B and 2B are each connected to an external connection terminal and to other internal circuit elements (the normal-withstand voltage element includes an 8V system power source circuit, and the intermediate-withstand voltage element includes a 12V system power source circuit) via a gate electrode, a source electrode, a drain electrode, and a substrate contact electrode.

Furthermore, although the protected element 1B, which is the normal-withstand voltage element, and the protected element 2B, which is the intermediate-withstand voltage element, have a common manufacturing process and are disposed on the same semiconductor substrate, both are independent of each other in terms of electrical circuitry.

Since the drain N-type diffusion region 208B is formed inward of the low-concentration N-type diffusion region 214, the protected element 2B, which is the intermediate-withstand voltage element, has a higher drain withstand voltage and Vt1 compared to an element including a normally-structured drain (a structure that is not surrounded by a low concentration N-type diffusion layer). Therefore, there is no need to consciously set the Vt1 of the ESD protection element 2A lower than the protected element 2B which is independent in terms of electrical circuitry. Inversely, as described in the third embodiment, in order to enhance the tolerance of the ESD protection element 2A as a protection element, it is preferable to increase the Vt1 of the ESD protection element 2A within a range that does not exceed the Vt1 of the protected element 2B.

In the present embodiment, the impurity elemental concentration of the low-concentration P-type diffusion regions 104 and 204 of the protected elements 1B and 2B, respectively, are set to, for example, approximately 3E16 cm⁻³. In this case, in order to set the Vt1 of the ESD protection element 1A to a desired value, ion injection and heat treatment are adjusted so that the impurity elemental concentration of the medium-concentration P-type diffusion region 102 becomes, for example, approximately 7E16 cm⁻³. Furthermore, in order to set the Vh of the ESD protection elements 1A and 2A to a desired value, ion injection and heat treatment are adjusted so that the respective impurity elemental concentrations of the high-concentration P-type diffusion region 103 of the ESD protection element 1A and the medium-concentration P-type diffusion region 102 of the ESD protection element 2A both become, for example, approximately 9E16 cm⁻³.

It should be noted that the aforementioned impurity elemental concentrations of the respective diffusion regions represent a relative value for an arbitrary reference value, and do not represent an absolute value for solving the problem.

With the above-described configuration, even in a semiconductor device including internal circuits having different maximum operating power source voltages, it is possible to efficiently form ESD protection circuits in which respective Vt1 and Vh are appropriately set independently of each other. Therefore, the triggering of malfunctioning of internal circuits located in the periphery of a protection circuit by the protection-operation of such protection circuits can be prevented.

### Fifth Embodiment

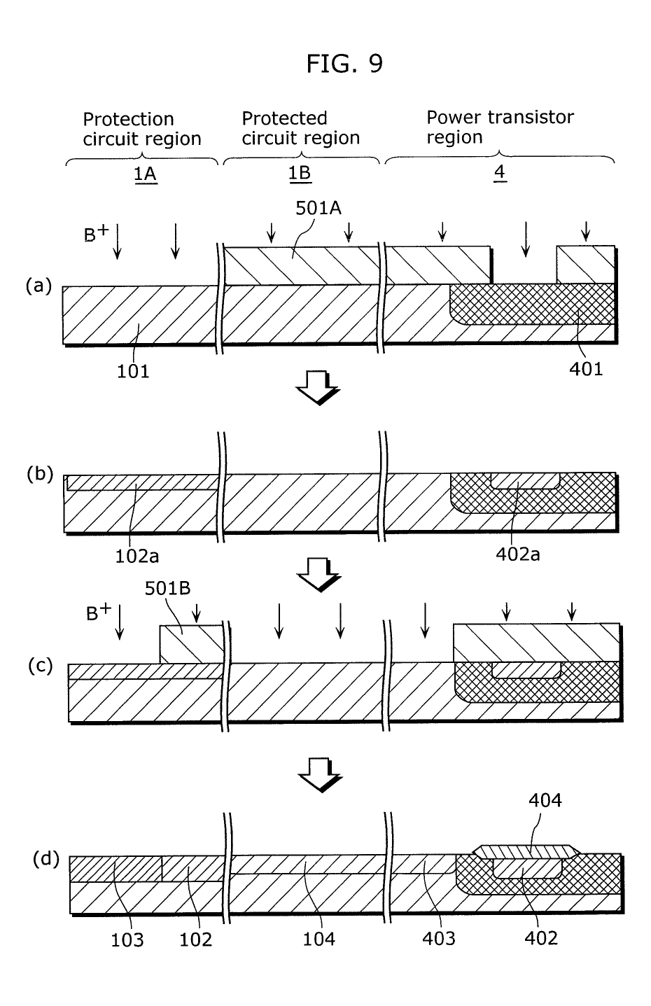

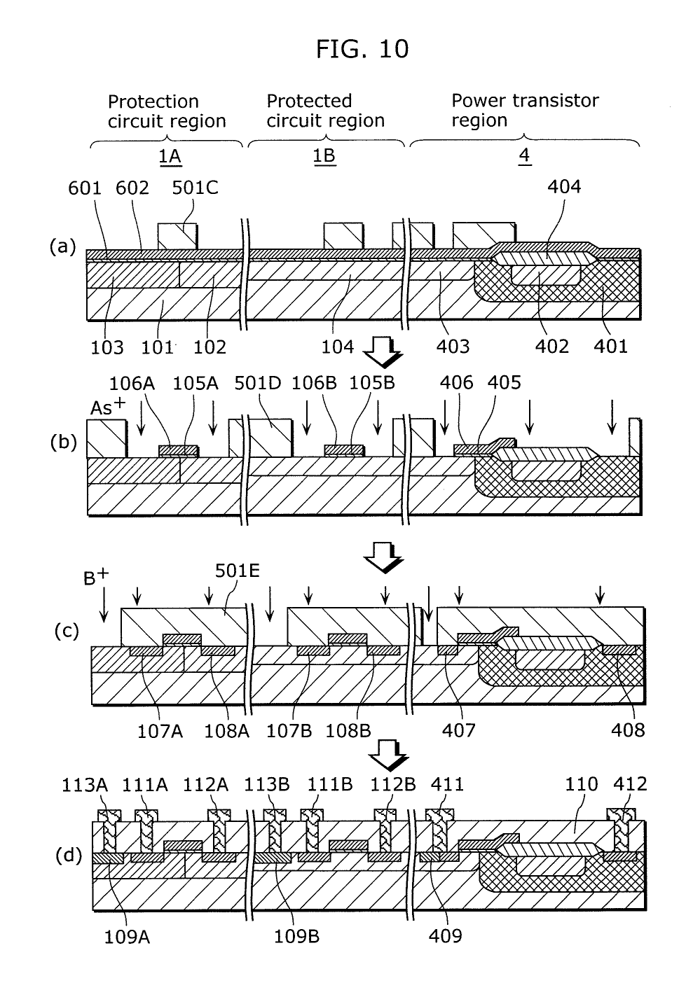

A method for manufacturing a semiconductor device in a fifth embodiment of the present invention shall be described with reference to FIG. 9 and FIG. 10. It should be noted that detailed description shall be made only for the main parts related to the present invention and part of processes that exist as common knowledge shall be omitted.

FIG. 9 and FIG. 10 are process cross-sectional views showing the method for manufacturing a semiconductor device in the fifth embodiment of the present invention. In FIG. 9 and FIG. 10, the ESD protection element 1A, the protected element 1B, and a power transistor element 4 are expediently illustrated next to each other in order to see the relationship between them.

The present embodiment shall describe a method of simultaneously forming an ESD protection circuit during the manufacturing process of an Intelligent Power Device (IPD) which includes both a power transistor part and a control circuit part thereof.

With a high-performance power device, such as the IPD, in which a control circuit and a power circuit are formed in a single chip, there are many cases where intermediate-withstand voltage or high-withstand voltage transistors are included together as a power transistor, a control circuit, a relay circuit therebetween, and a circuit for connecting with an external device. By executing the present invention during the manufacturing process of such a device, the device can be implemented more efficiently.

The IPD described here includes an extended drain (also called a drain extension) structure, and the manufacturing process includes a process of forming a deep (approximately 5 μm to 8 μm) N-type diffusion region having a low impurity concentration, and injecting approximately 1E13 cm⁻² of, for example, B⁺ (boron) ions at 100 keV to 150 keV. In the present invention, the P-type diffusion layer obtained from the aforementioned injection of B⁺ ions is efficiently used, and the P-type impurity is controlled to between, for example, 1E16 to 1E17 cm⁻³. This is aimed at reducing manufacturing costs by making use of the existing process. It goes without saying that implementation is also possible through the addition of an equivalent process, instead of using the IPD manufacturing process.

First, as a fourth injection process, a low-concentration N-type diffusion region 401, which is to be the extension drain of the power transistor element 4, is formed in the P-type Si substrate 101 having an impurity elemental concentration of, for example, approximately 1E14 cm⁻³, as shown in (a) in FIG. 9. Subsequently, approximately 1E13 to 1E14 cm⁻² of B⁺ ions are injected all at once at an accelerating voltage of 110 keV into the protection circuit region of the ESD protection element 1A as a first injection process, and into the protected circuit region of the protected element 1B using, as a mask, a resist pattern 501A that is open at part of the low-concentration N-type diffusion region 401 as a fifth injection process. Here, the first injection process, which is a manufacturing process of the ESD protection element 1A, and the fifth injection process, which is a manufacturing process of the power transistor element 4, are identical and simultaneously performed injection processes.

Next, the resist pattern 501A is removed as shown in (b) in FIG. 9. The above-described B⁺ ion injection forms an intermediate-concentration P-type diffusion region 102a, which is a first injection region, and an intermediate P-type diffusion region 402a, which is a preliminary step toward a first power transistor diffusion region.

Next, as shown in (c) in FIG. 9, approximately 1E12 to 1E13 cm⁻² of B⁺ ions are injected all at once at an accelerating voltage of 140 keV into: the protection circuit region using, as a mask, a resist pattern 501B which is open at a side of the ESD protection element 1A that will be the source, as a second injection process; the protected circuit region as a third injection process; and the power transistor region using, as a mask, the resist pattern 501 B that is open at a side of the power transistor element 4, as a sixth injection process. Here, the second injection process, which is a manufacturing process of the ESD protection element 1A, the third injection process, which is a manufacturing process of the protected element 1B, and the sixth injection process, which is a manufacturing process of the power transistor element 4, are identical and simultaneously performed injection processes.

Next, the resist pattern 501B is removed as shown in (d) in FIG. 9. Following thereafter, an element separating oxide film (here, an oxide film on the extension drain) 404 is formed (detailed step shall be omitted) and, in addition, drive-in is performed. Subsequently, as a first diffusion process, the high-concentration P-type diffusion region 103 is formed below what will be the source of the ESD protection element 1A through heat treatment of the P-type Si substrate 101. Furthermore, the medium-concentration P-type diffusion region 102 is formed below what will be the drain of the ESD protection element 1A. Furthermore, the low-concentration P-type diffusion region 104, which is the internal circuit diffusion region, is formed on the semiconductor substrate surface of the protected element 1B. In addition, a low-concentration P-type diffusion region 403, which is a second power transistor diffusion region, is formed below what will be the source of the power transistor element 4. Specifically, the high-concentration P-type diffusion region 103 is formed below what will be the source of the ESD protection element 1A, by an additional ion injection (second injection process) into and heat treatment (first diffusion process) of the medium-concentration P-type diffusion region 102a.

Next, as shown in (a) in FIG. 10, a gate oxide film (the gate oxide film and part of the element separating oxide film) 601 and a gate electrode film 602 of polysilicon are formed over the entire surface of the P-type Si substrate 101. Subsequently, a resist pattern 501C for forming a gate electrode is formed on the upper surface thereof.

Next, as shown in (b) in FIG. 10, patterning is performed on the gate electrode film 602 and the gate oxide film 601 by dry etching, using the resist pattern 501C as a mask. With this, gate insulation films 105A, 105B, and 405 and gate electrodes 106A, 106B, and 406 are formed. The processes described in aforementioned (a) and (b) in FIG. 10 are equivalent to a first gate forming process of the ESD protection element 1A and a second gate forming process of the protected element 1B. Here, the first gate forming process, which is a manufacturing process of the ESD protection element 1A, the second gate forming process, which is a manufacturing process of the protected element 1B, and a gate forming process of the power transistor element 4, are identical and simultaneously performed forming processes.

Subsequently, a resist pattern 501D which is open at a region that will be a source or a drain of an N channel element, is formed on each of the ESD protection element 1A, the protected element 1B, and the power transistor element 4. In addition, approximately 1E15 to 1E16 cm⁻² of As⁺ ions, for example, are injected at an accelerating voltage of 60 keV, through self-alignment using the gate electrodes 106A, 106B, and 406 as masks. This injection process is equivalent to a second diffusion process of the ESD protection device 1A and a third diffusion process of the protected element 1B. With this, a first surface diffusion region and a second surface diffusion region, which are of N-type, are formed in a part of the medium-concentration P-type diffusion region 102 and a part of the high-concentration P-type diffusion region 103, respectively. Furthermore, a third surface diffusion region and a fourth surface diffusion region, which are of N-type, are formed in a part of the low-concentration P-type diffusion region 104. Here, the second diffusion process, which is a manufacturing process of the ESD protection element 1A, the third diffusion process, which is a manufacturing process of the protected element 1B, are identical and simultaneously performed diffusion processes.

Next, the resist pattern 501D is removed as shown in (c) in FIG. 10. Subsequently, approximately 1E15 to 1E16 cm⁻² of B⁺ ions, for example, are injected at an accelerating voltage of 80 keV, using, as a mask, a resist pattern 501E which is open at a region (not shown in the figure) that will be a source or a drain of a new P channel element and at a contact portion to the P-type Si substrate 101.

Next, the resist pattern 501E is removed as shown in (d) in FIG. 10. Following subsequently, the inter-layer insulating film 110 is formed on the entire surface of the P-type Si substrate 101, and source electrodes 111A, 111B, and 411, the drain electrodes 112A, 112B, and 412, and the substrate contact electrodes 113A and 113B (the gate electrodes are not shown in the figure), are formed all at once via contact holes provided in the inter-layer insulating film 110.

With the above-described configuration and manufacturing method, it is possible to independently control the amount of impurity introduced to the P-type medium-concentration diffusion regions and the P-type high-concentration diffusion regions, and thus Vt and Vh can be set separately. Furthermore, since all the manufacturing processes needed to form the ESD protection element 1A are included in the manufacturing processes of the protected element 1B and the power transistor element 4, the desired ESD protection element 1A can be built into the semiconductor device without adding a new process.

### Sixth Embodiment

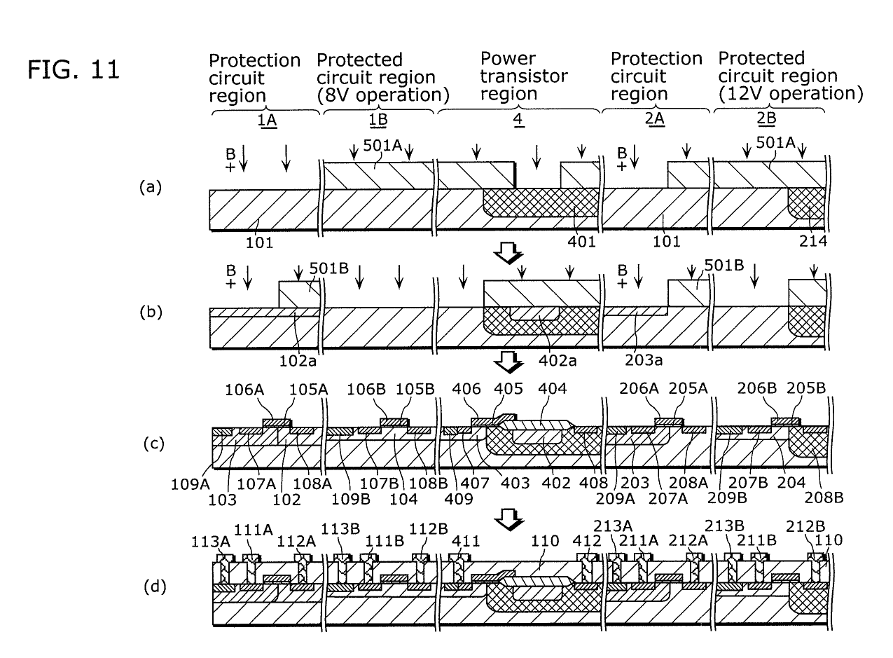

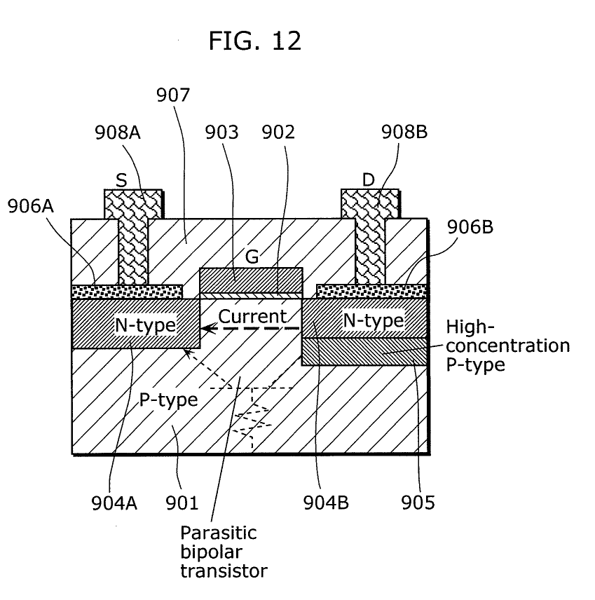

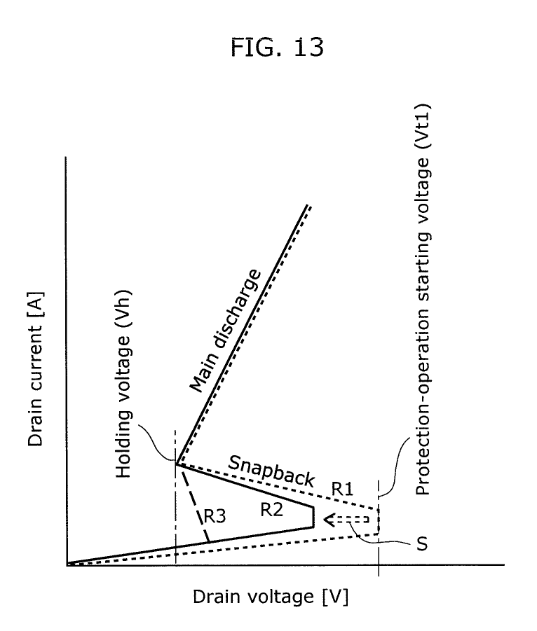

A method for manufacturing a semiconductor device in a sixth embodiment of the present invention shall be described with reference to FIG. 11. FIG. 11 is process cross-sectional view showing the method for manufacturing a semiconductor device in the sixth embodiment of the present invention. In FIG. 11, the ESD protection elements 1A and 2A, the protected elements 1B and 2B, and power transistor element 4 are expediently illustrated next to each other in order to see the relationship between them. It should be noted that detailed description shall be made only for the main parts related to the present invention and part of processes that exist as common knowledge shall be omitted.

The present embodiment shows a method for simultaneously forming, during the manufacturing process of an IPD provided with a withstand voltage of approximately 400 to 800V, a circuit operating at a normal voltage such as, for example, the protected element 1B of the 8V operating system circuit, and a circuit operating at an intermediate voltage such as, for example, the protected element 2B of the 12V operating system circuit. It should be noted that since the structure of the IPD and the characteristics of the manufacturing method have been described in the fifth embodiment, description shall be omitted here.

First, as shown in (a) in FIG. 11, the low-concentration N-type diffusion region 401, which is to be the extension drain of the power transistor element 4, and a low-concentration N-type diffusion region 214, which is to be the drain of the protected element 2B, are formed in the P-type Si substrate 101 having an impurity elemental concentration of, for example, approximately 1E14 cm−3, as a fourth injection process. Subsequently, approximately 1E13 to 1E14 cm⁻² of B+ ions, for example, are injected all at once at an accelerating voltage of 110 keV into: the protection circuit region of the ESD protection element 1A as a first injection process; the protection circuit region of the ESD protection element 2A using, as a mask, the resist pattern 501A which is open at a side of the ESD protection element 2A that will be the source, as the first injection process; and the power transistor region using, as a mask, the resist pattern 501A which is open at part of the low-concentration N-type diffusion region 401 as the fifth injection process. Here, the first injection process and the fifth injection process are identical and simultaneously performed injection processes.

Next, the resist pattern 501A is removed as shown in (b) in FIG. 11. The above-described B+ ion injection forms intermediate-concentration P-type diffusion regions 102a and 203a, and the intermediate P-type diffusion region 402a which is a preliminary step of a first power transistor diffusion region.

Subsequently, approximately 1E12 to 1E13 cm⁻² of B+ ions, for example, are injected all at once at an accelerating voltage of 140 keV into: the protection circuit regions of the ESD protection elements 1A and 2A using the resist pattern 501B which is open at the respective sides of the ESD protection elements 1A and 2A that will be a source, as a first injection process; the entirety of the protected element 1B, as a third injection process; the protected circuit region of the protected element 2B using, as a mask, the resist pattern 501B shielding the drain-side of the protected element 2B, as a third injection process; and the power transistor region using, as a mask, the resist pattern 501B which is open at a side of the power transistor element 4 that will be a source, as a sixth injection process. Here, the second injection process, the third injection process, and the sixth injection process are identical and simultaneously performed injection processes.

Next, the resist pattern 501B is removed as shown in (c) in FIG. 11. Following thereafter, the element separating oxide film (here, an oxide film on the extension drain) 404 is formed (detailed step shall be omitted) and, in addition, drive-in is performed. Subsequently, as a first diffusion process, the high-concentration P-type diffusion region 103 is formed below what will be the source of the ESD protection element 1A through heat treatment of the P-type Si substrate 101. Furthermore, the medium-concentration P-type diffusion region 102 is formed below what will be the drain of the ESD protection element 1A. Furthermore, the low-concentration P-type diffusion region 104 is formed on the semiconductor substrate surface of the protected element 1B. Furthermore, the high-concentration P-type diffusion region 103 is formed below what will be the source of the ESD protection element 1A. Furthermore, the low-concentration P-type diffusion region 204 is formed on the semiconductor substrate surface of the protected element 2B. Furthermore, the high-concentration P-type diffusion region 203 is formed below what will be the source of the ESD protection element 1A. In addition, the low-concentration P-type diffusion region 403 is formed below what will be the source of the power transistor element 4. Specifically, the high-concentration P-type diffusion regions 103 and 203 are formed below what will be the respective sources of the ESD protection elements 1A and 2A, through the additional ion injection (second injection process) into and the heat treatment of (first diffusion process) the medium-concentration P-type diffusion regions 102a and 203a, respectively.

Next, the gate insulation films 105A, 105B, 205A, 205B, and 405 and the gate electrodes 106A, 106B, 206A, 206B, and 406 are formed. Subsequently, a resist pattern (not shown in the figure) which is open at a region that will be a source or a drain of an N channel element, is formed on each of the ESD protection elements 1A and 2A, the protected elements 1B and 2B, and the power transistor element 4. In addition, approximately 1E15 to 1E16 cm⁻² of As+ ions are injected at an accelerating voltage of 60 keV, through self-alignment using the gate electrodes 106A, 106B, 206A, 206B, and 406 as masks. Next, after the above-mentioned resist pattern is removed, approximately 1E15 to 1E16 cm⁻² of B+ ions are injected at an accelerating voltage of 80 keV using, as a mask, a resist pattern (not shown in the figure) which is open at a region that will be a source or a drain of a new P channel element and at a contact portion to the P-type substrate.

Next, the above-mentioned resist pattern is removed as shown in (d) in FIG. 11. Following subsequently, the inter-layer insulating film 110 is formed on the entire surface of the P-type Si substrate 101, and the source electrodes 111A, 111B, 211A, 211B, and 411, the drain electrodes 112A, 112B, 212A, 212B, and 412, and the substrate contact electrodes 113A, 113B, 213A, and 213B (the gate electrodes are not shown in the figure), are formed via contact holes provided in the inter-layer insulating film 110.

With the above-described configuration and manufacturing method, ESD protection circuits having respective Vt1 and Vh1 that have been made appropriate can be efficiently formed on the same substrate, even in a semiconductor device including internal circuits having different operating voltages.

Although the semiconductor device according to the present invention has been described thus far based on the embodiments, the semiconductor device according to the present invention is not limited to the above-described embodiments. The present invention includes other embodiments implemented through a combination of arbitrary components of the first to sixth embodiments and modifications thereto, or modifications obtained through the application of various modifications to the first to sixth embodiments and the modifications thereto, that may be conceived by a person of ordinary skill in the art, that do not depart from the essence of the present invention, or various devices in which the semiconductor device according to the present invention is built into.

For example, the ESD protection element 1A which is a component of the semiconductor device 3 in the fourth embodiment may be changed to the ESD protection element 13A included in the semiconductor device 13 in the second embodiment.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be used in an ESD protection circuit of a semiconductor device and is useful in a semiconductor device for switching power supply, and in a manufacturing process thereof. In particular, since the process for manufacturing a power device having a withstand voltage of approximately 400V to 1000V includes a process that is suitable for the adjustment of the concentration of a P-type diffusion layer, the present invention is easily applicable to such a power device.

What is claimed is:

1. A semiconductor device comprising:
a semiconductor substrate of a second conductivity type;
an internal circuit composed of a transistor element using said semiconductor substrate; and
a protection circuit which protects said internal circuit against electrostatic discharge and is a transistor element using said semiconductor substrate,
wherein said protection circuit includes:
a first gate electrode which is formed above said semiconductor substrate and is grounded; and
a first electrode and a second electrode which are formed on said semiconductor substrate, each at an opposite side with respect to said first gate electrode, said first electrode and said second electrode being formed apart from said first gate electrode, and said second electrode being grounded;
a first diffusion region which is formed within said semiconductor substrate and is in contact with said second electrode, said first diffusion region being of a first conductivity type that is opposite in conductivity to the second conductivity type; and
a second diffusion region which is formed from under said first diffusion region to at least under part of said first gate electrode and covers said first diffusion region within said semiconductor substrate, said second diffusion region having a higher impurity concentration than an original region of said semiconductor substrate and being grounded at a same level as said first diffusion region,
said internal circuit includes:
a second gate electrode formed above said semiconductor substrate;
a third electrode and a fourth electrode which are formed on said semiconductor substrate, each at an opposite side with respect to said second gate electrode, said third electrode and said fourth electrode being formed apart from said second gate electrode, and
a third diffusion region which is formed under said third electrode and within said semiconductor substrate, and which is of the first conductivity type; and
a fourth diffusion region which is formed within said semiconductor substrate and has a highest second conductivity-type impurity concentration among regions in contact with said third diffusion region,
said third electrode is connected to said first electrode, and
said second diffusion region has a higher second conductivity-type impurity concentration than said fourth diffusion region.

2. The semiconductor device according to claim 1,
wherein a holding voltage, which is a characteristic value of said protection circuit, is higher than a maximum operating power source voltage at which normal operation of said internal circuit is guaranteed, the holding voltage being a minimum value of voltage generated between said first electrode and said second electrode immediately after conduction is created between said first electrode and said second electrode.

3. The semiconductor device according to claim 1,
wherein said protection circuit further includes:
a fifth diffusion region which is formed within said semiconductor substrate and is near or in contact with said first diffusion region and is in contact with said second diffusion region, said fifth diffusion region having a higher second conductivity-type impurity concentration than said second diffusion region, and
a fifth electrode which is formed on said semiconductor substrate, in contact with said fifth diffusion region, and which is grounded.

4. The semiconductor device according to claim 1, comprising
plural protection circuits including said protection circuit each of which is disposed corresponding to one of plural internal circuits including said internal circuit,
wherein the second conductivity-type impurity concentration of said second diffusion region is set separately for each of said protection circuits.

5. The semiconductor device according to claim 1,
wherein said protection circuit further includes:
a sixth diffusion region which is formed within said semiconductor substrate and is in contact with said first electrode, said sixth diffusion region being of the first conductivity type; and
a seventh diffusion region which is formed within said semiconductor substrate and is in contact with said sixth diffusion region, said seventh diffusion region being of the second conductivity type, and
said seventh diffusion region has a higher second conductivity-type impurity concentration than said fourth diffusion region when said third diffusion region is in contact with said third electrode.

6. The semiconductor device according to claim 5,
wherein said seventh diffusion region is formed from under said sixth diffusion region to under said first gate electrode and covers said sixth diffusion region within said semiconductor substrate.

7. The semiconductor device according to claim 5,
wherein said seventh diffusion region is not formed under said first gate electrode and is formed apart from said second diffusion region, said seventh diffusion region having a lower second conductivity-type impurity concentration than said second diffusion region.

8. The semiconductor device according to claim 5, comprising
plural protection circuits including said protection circuit each of which is disposed corresponding to one of plural internal circuits including said internal circuit,
wherein the second conductivity-type impurity concentration of said seventh diffusion region is set separately for each of said protection circuits.

9. The semiconductor device according to claim 1,
wherein said protection circuit further includes:
a sixth diffusion region which is formed within said semiconductor substrate and is in contact with said first electrode, said sixth diffusion region being of the first conductivity type; and
a seventh diffusion region which is formed within said semiconductor substrate and is in contact with said sixth diffusion region, said seventh diffusion region being of the second conductivity type,
said third diffusion region has a lower first conductivity-type impurity concentration than said sixth diffusion region, and
said seventh diffusion region has a second conductivity-type impurity concentration equal to or higher than the second conductivity-type impurity concentration of the original region of said semiconductor substrate.

10. The semiconductor device according to claim 9, comprising
plural protection circuits including said protection circuit each of which is disposed corresponding to one of plural internal circuits including said internal circuit,
wherein the second conductivity-type impurity concentration of said seventh diffusion region is set separately for each of said protection circuits.

11. A method for manufacturing a semiconductor device, the semiconductor device including:
a semiconductor substrate of a second conductivity type;
an internal circuit composed of a transistor element using a first region of the semiconductor substrate;
a protection circuit which protects the internal circuit against electrostatic discharge and is a transistor element using a second region of the semiconductor substrate, the second region being different from the first region, and
said method comprising:
forming the internal circuit; and
forming the protection circuit,
wherein said forming of a protection circuit includes:
forming a first injection region on a surface of the semiconductor substrate of the second conductivity type by blanket irradiating an ion species of the second conductivity type, the first injection region having a higher second conductivity-type impurity concentration than an original region of the semiconductor substrate that is not injected with the ion species;
forming a second injection region and a third injection region on the surface of the semiconductor substrate by opening at least parts of the first injection region and blanket irradiating an ion species of the second conductivity type after said forming of a first injection region, the second injection region having a second conductivity-type impurity concentration equal to or higher than a second conductivity-type impurity concentration of the original region, and the third injection region having a higher second conductivity-type impurity concentration than the second injection region;
heat-diffusing the second injection region and the third injection region to create a medium-concentration diffusion region and a high-concentration diffusion region, respectively, by heat-treating the semiconductor substrate after said forming of a second injection region and a third injection region;
forming a first gate electrode on the surface of the semiconductor substrate after said heat-diffusing so that the first gate electrode is in contact with the high-concentration diffusion region and is near or is in contact with the medium-concentration diffusion region;
forming a first surface diffusion region and a second surface diffusion region, which are of the first conductivity type, in part of the medium-concentration diffusion region and part of the high-concentration diffusion region, respectively, within the semiconductor substrate and near the surface of the semiconductor substrate, after said forming of a first gate electrode; and
forming a first electrode and a second electrode on the surface of the semiconductor substrate after said forming of a first surface diffusion region and a second surface diffusion region, the first electrode being connected to the internal circuit and in contact with only the first surface diffusion region, and the second electrode being in contact with only the second surface diffusion region.

12. The method for manufacturing a semiconductor device according to claim 11,
wherein said forming of an internal circuit includes:
forming an internal circuit diffusion region on the surface of the semiconductor substrate by injecting an ion species of the second conductivity type into the surface of the semiconductor substrate, the internal circuit diffusion region having a higher second conductivity-type impurity concentration than the original region;
forming a second gate electrode on the surface of the semiconductor substrate after said forming of an internal circuit diffusion region;
forming a third surface diffusion region and a fourth surface diffusion region within the semiconductor substrate, each at an opposite side with respect to the second gate electrode, after said forming of a second gate electrode; and
forming a third electrode and a fourth electrode on the surface of the semiconductor substrate after said forming of a third surface diffusion region and a fourth surface diffusion region, the third electrode being connected to the first electrode of the protection circuit and in contact with only the third surface diffusion region, and the fourth electrode being in contact with only the fourth surface diffusion region,
in said forming of an internal circuit diffusion region, the internal circuit diffusion region is formed by blanket irradiating the ion species of the second conductivity type simultaneously with said forming of a first injection region or said forming of a second injection region and a third injection region,
in said forming of a third surface diffusion region and a fourth surface diffusion region, the third surface diffusion region and the fourth surface diffusion region are formed by blanket irradiating an ion species of the first conductivity type simultaneously with said forming of a first surface diffusion region and a second surface diffusion region,
in said forming of a third electrode and a fourth electrode, the third electrode and the fourth electrode are formed simultaneously with and in a same process as said forming of a first electrode and a second electrode, and
in said forming of a first injection region, said forming of a second injection region and a third injection region, and said heat-diffusing, the high-concentration diffusion region is formed so as to have a higher second conductivity-type impurity concentration than a region of the second conductivity type which is formed within the semiconductor substrate and is in contact with or is near the third surface diffusion region.

13. The method for manufacturing a semiconductor device according to claim 11, further comprising:
forming a power transistor included in the semiconductor device,
wherein said forming of a power transistor includes:
forming a low-concentration diffusion region which serves as an extension drain of the first conductivity type, by injecting an ion species of the first conductivity type into a surface of a third region of the semiconductor substrate that is different from the first region;
forming a first power transistor diffusion region in part of the low-concentration diffusion region after said forming of a low-concentration diffusion region, the first power transistor diffusion region having a higher second conductivity-type impurity concentration than the original region of the semiconductor substrate; and
forming a second power transistor diffusion region within the semiconductor substrate, in a region other than the low-concentration diffusion region, after said forming of a low-concentration diffusion region, the second power transistor diffusion region having a higher second conductivity-type impurity concentration than the original region, and
in said forming of a first power transistor diffusion region and said forming of a second power transistor diffusion region, the first power transistor diffusion region and the second power transistor diffusion region are respectively formed by blanket irradiating an ion species of the second conductivity type simultaneously with said forming of a first injection region and said forming of a second injection region and a third injection region.

14. The method for manufacturing a semiconductor device according to claim 11,
wherein said forming of a protection circuit further includes:
forming a fifth surface diffusion region of the second conductivity type after said heat-diffusing, by injecting an ion species of the second conductivity type into a region which is part of the high-concentration diffusion region and is near or in contact with the second surface diffusion region; and
forming a fifth electrode on the surface of the semiconductor substrate and in contact with only the fifth surface diffusion region after said forming of an internal circuit diffusion region, the fifth electrode being grounded.

15. The method for manufacturing a semiconductor device according to claim 11,
wherein in said forming of a first injection region, said forming of a second injection region and a third injection region, and said heat-diffusing:
when a region which is formed within the semiconductor substrate and is in contact with the third surface diffusion region is of the second conductivity type, the medium-concentration diffusion region is formed so as to have a higher second conductivity-type impurity concentration than the region, and
when the region which is formed within the semiconductor substrate and is in contact with the third surface diffusion region is of the first conductivity type, the medium-concentration diffusion region is formed so as to have a second conductivity-type impurity concentration equal to or higher than the second conductivity-type impurity concentration of the original region of the semiconductor substrate.
